(19) United States
(12) Patent Application Publication
(10) Pub. No.: US 2025/0356936 A1
(43) Pub. Date: Nov. 20, 2025

(54) METHOD OF PROCESSING METADATA AND MEMORY DEVICE PERFORMING THE METHOD

(71) Applicant: SK hynix Inc., Icheon-si Gyeonggi-do (KR)

(72) Inventor: Kyeong Pil KANG, Icheon-si Gyeonggi-do (KR)

(73) Assignee: SK hynix Inc., Icheon-si Gyeonggi-do (KR)

(21) Appl. No.: 18/896,156

(22) Filed: Sep. 25, 2024

(30) Foreign Application Priority Data
May 20, 2024 (KR) 10-2024-0065480

(51) Int. Cl. G11C 29/12; G11C 29/18; G11C 29/30

(52) U.S. Cl. CPC G11C 29/1201; G11C 29/30; G11C 2029/1802

(57) ABSTRACT

A memory device include a plurality of memory cores and a plurality of meta storage circuits, each of the plurality of meta storage circuits corresponding to a different one of the plurality of memory cores. In an embodiment, when a meta write operation is performed, data that are received through an external line are stored in the plurality of memory cores based on a column address, and metadata that are received through a meta line are stored in a meta storage circuit, among the plurality of meta storage circuits, that is selected by the column address.

### CROSS-REFERENCE TO RELATED APPLICATION

The present application claims priority under 35 U.S.C. § 119 (a) to Korean Patent Application No. 10-2024-0065480, filed in the Korean Intellectual Property Office on May 20, 2024, the entire contents of which application is incorporated herein by reference.

### BACKGROUND

### 1. Technical Field

The present disclosure relates to a method of processing metadata and a memory device performing the method.

### 2. Related Art

In general, a memory device stores metadata including detailed information on a characteristic and construction of data in order to effectively manage and manipulate the data. The metadata may include a physical address and logical address of memory and information on the size and type of data. The memory device may include a storage device that stores the metadata and may include various circuits that control an operation that stores or outputs the metadata.

### SUMMARY

In an embodiment, a memory device may include a plurality of memory cores and a plurality of meta storage circuits, each of the plurality of meta storage circuits corresponding to a different one of the plurality of memory cores. In an embodiment, when a meta write operation is performed, data that are received through an external line may be stored in the plurality of memory cores based on a column address, and metadata that are received through a meta line may be stored in a meta storage circuit, among the plurality of meta storage circuits, that is selected by the column address.

In an embodiment of the present disclosure, when a meta read operation is performed, the data stored in the plurality of memory cores may be output to the external line based on the column address. When the meta read operation is performed, the metadata stored in the storage circuit, among the plurality of meta storage circuits, that is selected by the column address may be output to the meta line.

In an embodiment of the present disclosure, when an internal meta write operation is performed, metadata stored in the plurality of meta storage circuits may be output to a read meta line based on a column address. When the internal meta write operation is performed, the metadata that are received through the read meta line may be stored in the plurality of memory cores based on the column address.

In an embodiment of the present disclosure, when an internal meta read operation is performed, metadata stored in the plurality of memory cores may be output to a write meta line based on a column address. When the internal meta read operation is performed, the metadata that are received through the write meta line may be stored in the plurality of meta storage circuits based on the column address.

In an embodiment of the present disclosure, when a meta parallel-write operation is performed, a test voltage may be stored in the plurality of meta storage circuits. When the meta parallel-write operation is performed, the test voltage stored in the plurality of meta storage circuits may be stored in the plurality of memory cores. When a meta parallel-read operation is performed, the test voltage that is stored in the plurality of memory cores may be output to an external line.

In an embodiment, a method of processing metadata may include, when a meta write operation is performed, storing data that are received through an external line in a plurality of memory cores, based on a column address and storing metadata that are received through a meta line in at least one meta storage circuit, among a plurality of meta storage circuits, that is selected by the column address.

In an embodiment, a method of processing metadata may include, when a meta read operation is performed, outputting data stored in a plurality of memory cores to an external line, based on a column address and outputting to a meta line metadata stored in a meta storage circuit, among a plurality of meta storage circuits, that is selected by the column address.

In an embodiment, a method of processing metadata may include when an internal meta write operation is performed, outputting to a read meta line metadata stored in a plurality of meta storage circuits to a read meta line based on a column address and storing the metadata that are received through the read meta line in a plurality of memory cores based on the column address.

In an embodiment, a method of processing metadata may include, when an internal meta read operation is performed, outputting to a write meta line metadata stored in a plurality of memory cores based on a column address and storing metadata that are received through the write meta line in a plurality of meta storage circuits based on the column address.

In an embodiment, a method of processing metadata may include storing a test voltage in a plurality of meta storage circuits when a meta parallel-write operation is performed, storing the test voltage stored in the plurality of meta storage circuits in a plurality of memory cores when the meta parallel-write operation is performed, and outputting, to an external line, the test voltage that is stored in the plurality of memory cores when the meta parallel-read operation is performed.

### BRIEF DESCRIPTION OF THE DRAWINGS

FIG. 1 illustrates a memory system according to an example of the present disclosure.

FIG. 2 illustrates a memory device according to an example of the present disclosure.

FIG. 3 illustrates a meta control circuit and a meta storage circuit according to an example of the present disclosure.

FIG. 4 illustrates an example of the meta storage circuit according to the present disclosure.

FIG. 5 illustrates a circuit of a meta register according to an example of the present disclosure.

FIG. 6 illustrates a metadata driver according to an example of the present disclosure.

FIG. 7 illustrates an input and output line driver according to an example of the present disclosure.

FIG. 8 illustrates a table including data utilized in a meta mode operation that is performed based on a column address according to an example of the present disclosure.

FIG. 9 illustrates a memory device during an operation including storing data and metadata during a meta write operation according to an embodiment of the present disclosure.

FIG. 10 illustrates a timing diagram during a meta write operation including storing metadata based on a column address according to an embodiment of the present disclosure.

FIG. 11 illustrates a path along which data and metadata are stored during a meta write operation in a memory device according to an embodiment of the present disclosure.

FIG. 12 illustrates a metadata driver during a meta write operation including outputting received metadata to a write meta line according to an embodiment of the present disclosure.

FIG. 13 illustrates a circuit of a meta register during a meta write operation including storing received metadata in a data latch according to an embodiment of the present disclosure.

FIG. 14 illustrates an input and output line driver during a meta write operation including outputting received data to an internal line during a meta write operation according to an embodiment of the present disclosure.

FIG. 15 illustrates a memory device during a meta read operation including output of data and metadata according to an embodiment of the present disclosure.

FIG. 16 illustrates a timing diagram during a meta read operation including output of metadata stored in the meta registers based on a column address according to an embodiment of the present disclosure.

FIG. 17 illustrates a path along which data and metadata are output during a meta read operation in a memory device according to an embodiment of the present disclosure.

FIG. 18 illustrates a circuit of a meta register during a meta read operation including output to a read meta line of metadata stored in the data latch according to an embodiment of the present disclosure.

FIG. 19 illustrates a metadata driver during an operation including output to the meta line of metadata that are received through the read meta line according to an embodiment of the present disclosure.

FIG. 20 illustrates an input and output line driver during a meta read operation including output to the external line BGIO of data that are received through the internal line according to an embodiment of the present disclosure.

FIG. 21 illustrates a memory device during an internal meta write operation including storing metadata that are output by meta storage circuits in memory cores according to an embodiment of the present disclosure.

FIG. 22 illustrates a timing diagram during an internal meta write operation including outputting and storing metadata based on a column address according to an embodiment of the present disclosure.

FIG. 23 illustrates a path along which metadata are output from the meta storage circuits and a path along which metadata are stored in the memory cores during an internal meta write operation in a memory device according to an embodiment of the present disclosure.

FIG. 24 illustrates a circuit of a meta register during an internal meta write operation including output to the read meta line of metadata stored in the meta register to an embodiment of the present disclosure.

FIG. 25 illustrates an input and output line driver during an internal meta write operation including output to the internal line of metadata that are received through the read meta line according to an embodiment of the present disclosure.

FIG. 26 illustrates a memory device during an internal meta read operation including storing in the meta storage circuit metadata that are output by the memory core according to an embodiment of the present disclosure.

FIG. 27 illustrates a timing diagram during an internal meta read operation including output of metadata by the memory cores and storing metadata in the meta storage circuits based on a column address according to an embodiment of the present disclosure.

FIG. 28 illustrates a path along which metadata are output by the memory cores and metadata are stored in the meta storage circuits during an internal meta read operation in a memory device according to an embodiment of the present disclosure.

FIG. 29 illustrates a metadata driver during an internal meta read operation including output to the write meta line of metadata that are received through the internal line according to an embodiment of the present disclosure.

FIG. 30 illustrates a circuit of a meta register during an internal meta read operation including storing in the data latch metadata that are received through the write meta line according to an embodiment of the present disclosure.

FIG. 31 illustrates an example of a metadata driver for a meta parallel-write operation according to an embodiment of the present disclosure.

FIG. 32 illustrates a path along which a test voltage is output by the meta storage circuits and a path along which a test voltage is stored in the memory cores during a meta parallel-write operation in a memory device according to an embodiment of the present disclosure.

FIG. 33 illustrates a circuit of a meta register during a meta parallel-write operation including output to the read meta line of a test voltage that is stored in the meta register according to an embodiment of the present disclosure.

FIG. 34 illustrates an input and output line driver during a meta parallel-write operation including output to the internal line of metadata that are received through the read meta line according to an embodiment of the present disclosure.

FIG. 35 illustrates a path along which test voltages stored in the memory cores is output during a meta parallel-read operation in a memory device according to an embodiment of the present disclosure.

FIG. 36 illustrates an input and output line driver during a meta parallel-read operation including output to the external line of data that are received through the internal line according to an embodiment of the present disclosure.

### DETAILED DESCRIPTION

The term “meta” when used in conjunction with other terms such as “meta mode,” “meta read,” “meta write,” and so forth, is an abbreviation for “metadata” throughout the present disclosure.

Terms such as “first” and “second,” which are used to distinguish among various components, do not imply size, order, priority, quantity, or importance of the components. For example, a first component may be referred to as a second component, and vice versa.

When one component is referred to as “connected” to another component, the components may be directly connected to each other or connected to each other through an intervening component. When one component is referred to as “directly connected” to another component, the components are directly connected to each other without an intervening component.

A “logic high level” and a “logic low level” are used to describe the logic levels of signals. A signal at a logic high level is distinguished from a signal at a logic low level. For example, when a signal at a first voltage corresponds to a signal at a logic high level, a signal at a second voltage corresponds to a signal at a logic low level. According to an embodiment, a voltage for a logic high level is a voltage higher than a voltage for a logic low level. According to an embodiment, the logic levels of signals may be set to different logic levels or opposite logic levels. For example, a signal at a logic high level may be at a logic low level in some embodiments, and a signal at a logic low level may be at a logic high level in some embodiments.

A “bit set” includes a combination of logic levels of bits included in a signal. When a logic level of each of the bits included in the signal is changed, a bit set of the signal is changed. For example, when two bits are included in a signal, a bit set for the signal includes a first bit set when logic levels of the two bits included in the signal are a logic low level and a logic low level and includes a second bit set when logic levels of the two bits included in the signal are a logic low level and a “logic high level.

The present disclosure is described in detail through embodiments. The embodiments are only used to provide examples within the present disclosure, and the scope of the present disclosure is not limited by the embodiments.

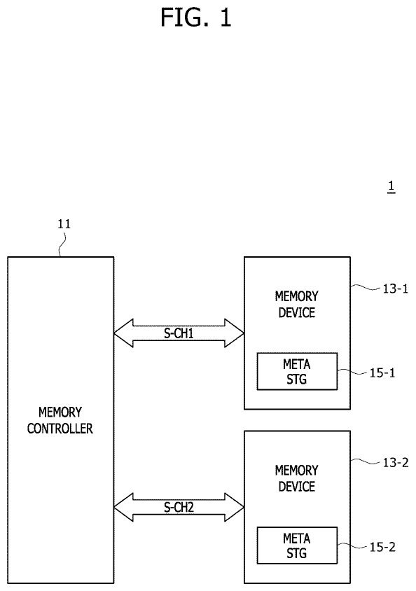

FIG. 1 illustrates a memory system 1 according to an example of the present disclosure. As illustrated in FIG. 1, in an embodiment, the memory system 1 includes a memory controller 11, a first memory device 13-1, and a second memory device 13-2.

The memory controller 11 controls a write operation, a read operation, and a meta mode operation for the first memory device 13-1 to be performed through a first sub-channel S-CH1, for example. The meta mode operation includes, for example, a meta write operation, a meta read operation, an internal meta write operation, and an internal meta read operation. The memory controller 11 transmits data to the first memory device 13-1 through the first sub-channel S-CH1 when a write operation is performed and receives data from the first memory device 13-1 through the first sub-channel S-CH1 when a read operation is performed. The memory controller 11 transmits data and metadata to the first memory device 13-1 through the first sub-channel S-CH1 when a meta write operation is performed, and receives data and metadata from the first memory device 13-1 through the first sub-channel S-CH1 when a meta read operation is performed. The memory controller 11 transmits data to the second memory device 13-2 through the second sub-channel S-CH2 when a write operation is performed, and receives data from the second memory device 13-2 through the second sub-channel S-CH2 when a read operation is performed. The memory controller 11 transmits data and metadata to the second memory device 13-2 through the second sub-channel S-CH2 when a meta write operation is performed and receives data and metadata from the second memory device 13-2 through the second sub-channel S-CH2 when a meta read operation is performed. Each of the first sub-channel S-CH1 and the second sub-channel S-CH2 may communicate thirty-two bits in parallel in this example, although the present disclosure is not limited to this example.

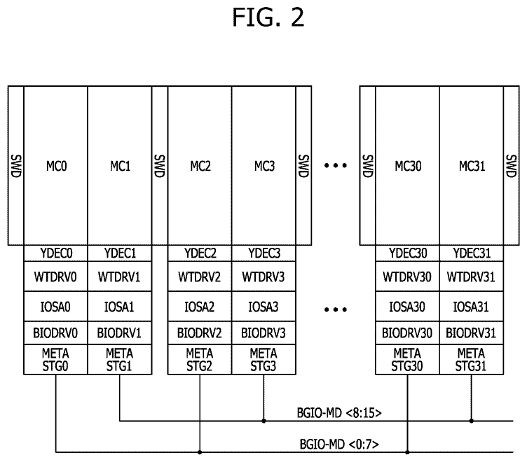

The first memory device 13-1 stores data that are received from the memory controller 11 in memory cores, for example, MC0 to MC31 in FIG. 2 when a write operation is performed, for example. The first memory device 13-1 transmits data stored in the memory cores to the memory controller 11 when a read operation is performed, for example. The first memory device 13-1 stores data that are received from the memory controller 11 in the memory cores and stores metadata in a first meta storage circuit META STG 15-1, when a meta write operation is performed, for example. The first memory device 13-1 transmits, to the memory controller 11, data stored in the memory cores and metadata stored in the first meta storage circuit 15-1, when a meta read operation is performed, for example. The first memory device 13-1 stores, in the memory cores, metadata stored in the first meta storage circuit 15-1, when an internal meta write operation is performed, for example. The first memory device 13-1 stores, in the first meta storage circuit 15-1, metadata stored in the memory cores, when an internal meta read operation is performed, for example.

The second memory device 13-2 stores, in the memory cores, data that are received from the memory controller 11, when a write operation is performed, for example. Memory cores of the second memory device 13-2 and memory cores of the first memory device 13-1 are distinguished or different from each other. The second memory device 13-2 transmits data stored in the memory cores to the memory controller 11 when a read operation is performed. The second memory device 13-2 stores data that are received from the memory controller 11 in the memory cores and stores metadata that are received from the memory controller 11 in a second meta storage circuit META STG 15-2, when a meta write operation is performed, for example. The second memory device 13-2 transmits, to the memory controller 11, data stored in the memory cores and metadata stored in the second meta storage circuit 15-2, when a meta read operation is performed, for example. The second memory device 13-2 stores metadata stored in the second meta storage circuit 15-2 in the memory cores, when an internal meta write operation is performed, for example. The second memory device 13-2 stores, the second meta storage circuit 15-2, metadata stored in the memory cores, when an internal meta read operation is performed, for example.

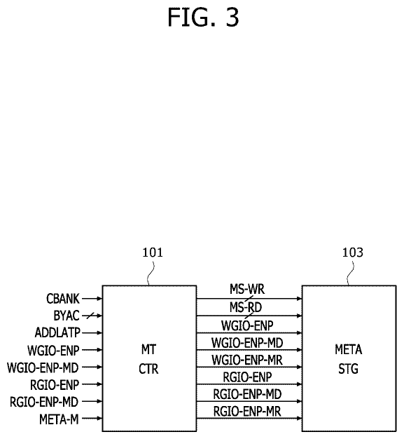

FIG. 2 illustrates a memory device according to an example of the present disclosure. The memory device illustrated in FIG. 2 is an example of an implementation of the first memory device 13-1 and/or the second memory device 13-2 illustrated in FIG. 1. As illustrated in FIG. 2, in an embodiment, the memory device includes memory cores MC0 to MC31, sub-word lines SWD, column decoders YDEC0 to YDEC31, write drivers WTDRV0 to WTDRV31, input and output sense amplifiers IOSA0 to IOSA31, input and output line drivers BIODRV0 to BIODRV31, meta storage circuits META STG0 to META STG31, and meta lines BGIO-MD<0:7> and BGIO-MD<0:8>. The memory device may perform a meta mode operation based on a column address, for example, BYAC<4:9> in FIG. 3. A meta write operation, a meta read operation, an internal meta write operation, and an internal meta read operation that are included in the meta mode operation of the memory device are described as follows.

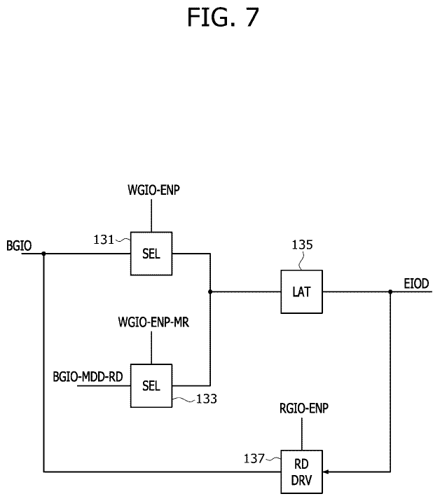

When a meta write operation is performed based on the column address, data that are received through an external line, for example, BGIO in FIG. 7, are stored in the memory cores MC0 to MC31 by the input and output line drivers BIODRV0 to BIODRV31, the write drivers WTDRV0 to WTDRV31, and the column decoders YDEC0 to YDEC31. For example, when a meta write operation is performed, data totaling 256 bits are stored in the memory cores MC0 to MC31, where 8 bits are stored in each of the 32 memory cores MC0 to MC31, based on a column selection signal, for example, YI0, among YI0 to YI59, which is selected or identified by the column address. For example, when a meta write operation is performed based on the column address, metadata that are received through the meta lines BGIO-MD<0:7> and BGIO-MD<8:15> are stored in two meta storage circuits that are selected by the column address among the meta storage circuits META STG0 to META STG31. For example, when the meta storage circuits META STG0 and META STG1 (hereinafter indicated by “META STG0/1”) are selected by the column address during a meta write operation, metadata that are received through the meta lines BGIO-MD<0:7> and BGIO-MD<8:15> are driven by the input and output line drivers BIODRV0 and BIODRV1, such that the metadata totaling 16 bits is stored in the meta storage circuits META STG0/1, where 8 bits are stored in each of the meta storage circuits META STG0/1.

When a meta read operation is performed based on the column address, data stored in the memory cores MC0 to MC31 is output through an external line, for example, BGIO in FIG. 7, by the column decoders YDEC0 to YDEC31, the input and output sense amplifiers IOSA0 to IOSA31, and the input and output line drivers BIODRV0 to BIODRV31. For example, when a meta read operation is performed, data totaling 256 bits stored in the memory cores MC0 to MC31, 8 bits from each memory core MC0 to MC31, may be output through the external line based on a column selection signal, for example, YI0, among YI0 to YI59, which is selected by the column address. For example, when a meta read operation is performed based on the column address, metadata stored in two meta storage circuits, among the meta storage circuits META STG0 to META STG31, are output through the meta lines BGIO-MD<0:7> and BGIO-MD<8:15>. For example, when the meta storage circuits META STG0/1 are selected by the column address during a meta read operation, metadata totaling 16 bits, including 8 bits stored in each of the meta storage circuits META STG0/1, may be driven by the input and output line drivers BIODRV0 and BIODRV1 and output through the meta lines BGIO-MD<0:7> and BGIO-MD<8:15>.

For example, when an internal meta write operation is performed based on the column address, metadata stored in the meta storage circuits META STG0 to META STG31 may be driven and output by the input and output line drivers BIODRV0 and BIODRV1, and are stored in the memory cores MC0 to MC31, respectively, by the column decoders YDEC0 to YDEC31 and the write drivers WTDRV0 to WTDRV31, respectively. For example, during an internal meta write operation, metadata totaling 256 bits stored in the meta storage circuits META STG0/1 may be stored in the memory cores MC0 to MC31, where 8 bits are stored in each of the 32 memory cores MC0 to MC31, based on a column selection signal, for example, YI60, among YI60 to YI63, which is selected by the column address.

For example, when an internal meta read operation is performed based on the column address, metadata stored in the memory cores MC0 to MC31 are output by the column decoders YDEC0 to YDEC31 and the input and output sense amplifiers IOSA0 to IOSA31, are driven by the input and output line drivers BIODRV0 and BIODRV1, and are stored in the meta storage circuits META STG0 to META STG31, respectively. For example, during an internal meta read operation, metadata totaling 256 bits, 8 bits from each memory core MC0 to MC31, that are output by the memory cores MC0 to MC31 based on a column selection signal, for example, YI60, among YI60 to YI63, which is selected by the column address, are stored in the meta storage circuits META STG0 to META STG31, respectively.

FIG. 3 illustrates a meta control circuit MT CTR 101 and a meta storage circuit META STG 103 according to an example of the present disclosure.

The meta control circuit 101 generates a latch input signal MS-WR, a latch output signal MS-RD, an internal meta write pulse WGIO-ENP-MR, and an internal meta read pulse RGIO-ENP-MR based on a column bank signal CBANK, a column address BYAC, an address latch pulse ADDLATP, a write pulse WGIO-ENP, a meta write pulse WGIO-ENP-MD, a read pulse RGIO-ENP, a meta read pulse RGIO-ENP-MD, and a meta mode signal META-M. The column bank signal CBANK is generated for each bit of metadata that are input and output when a meta mode operation is performed based on the column address BYAC for each bank. The column address BYAC is generated in order to select a memory core to and from which data are input and output or to select a memory core and a meta storage circuit to and from which metadata are input and output during a meta mode operation. The address latch pulse ADDLATP is sequentially generated in synchronization with the column bank signal CBANK to latch the column address BYAC during a meta mode operation. The write pulse WGIO-ENP and the meta write pulse WGIO-ENP-MD are generated when a meta write operation is performed during a meta mode operation. The write pulse WGIO-ENP and the meta write pulse WGIO-ENP-MD may be generated after the column bank signal CBANK and the address latch pulse ADDLATP are generated. The internal meta write pulse WGIO-ENP-MR is generated when an internal meta write operation is performed during a meta mode operation. The internal meta write pulse WGIO-ENP-MR may be generated after the column bank signal CBANK and the address latch pulse ADDLATP are generated. The read pulse RGIO-ENP and the meta read pulse RGIO-ENP-MD are generated when a meta read operation is performed during a meta mode operation. The read pulse RGIO-ENP and the meta read pulse RGIO-ENP-MD may be generated after the column bank signal CBANK and the address latch pulse ADDLATP are generated. The internal meta read pulse RGIO-ENP-MR are generated when an internal meta read operation is performed during a meta mode operation. The internal meta read pulse RGIO-ENP-MR may be generated after the column bank signal CBANK and the address latch pulse ADDLATP are generated. The latch input signal MS-WR are generated when a meta write operation or an internal meta read operation is performed during a meta mode operation. The latch input signal MS-WR may be generated after the column bank signal CBANK and the address latch pulse ADDLATP are generated. The latch output signal MS-RD are generated when a meta read operation or an internal meta write operation is performed during a meta mode operation. The latch output signal MS-RD may be generated after the column bank signal CBANK and the address latch pulse ADDLATP are generated. The meta control circuit 101 is electrically connected to the meta storage circuit 103 and outputs the latch input signal MS-WR, the latch output signal MS-RD, the write pulse WGIO-ENP, the meta write pulse WGIO-ENP-MD, the internal meta write pulse WGIO-ENP-MR, the read pulse RGIO-ENP, the meta read pulse RGIO-ENP-MD, and the internal meta read pulse RGIO-ENP-MR to the meta storage circuit 103.

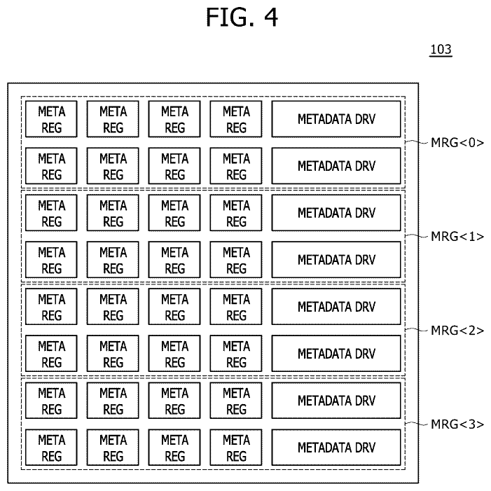

The meta storage circuit 103 stores and outputs metadata based on the latch input signal MS-WR, the latch output signal MS-RD, the write pulse WGIO-ENP, the meta write pulse WGIO-ENP-MD, the internal meta write pulse WGIO-ENP-MR, the read pulse RGIO-ENP, the meta read pulse RGIO-ENP-MD, and the internal meta read pulse RGIO-ENP-MR. For example, when a meta write operation is performed during a meta mode operation, the meta storage circuit 103 stores metadata that are received through a meta line in a meta register, for example, a meta register that is selected by the latch input signal MS-WR, among meta registers META REG in FIG. 4, based on the write pulse WGIO-ENP and the meta write pulse WGIO-ENP-MD. For example, when a meta read operation is performed during a meta mode operation, the meta storage circuit 103 outputs metadata stored in a meta register, for example, a meta register that is selected by the latch output signal MS-RD, among the meta registers META REG in FIG. 4, through a meta line based on the read pulse RGIO-ENP and the meta read pulse RGIO-ENP-MD. For example, when an internal meta write operation is performed during a meta mode operation, the meta storage circuit 103 outputs metadata stored in a meta register, for example, a meta register that is selected by the latch output signal MS-RD, among the meta registers META REG in FIG. 4, to store the metadata in a memory core based on the internal meta write pulse WGIO-ENP-MR. For example, when an internal meta read operation is performed during a meta mode operation, the meta storage circuit 103 stores metadata that are output by a memory core in a meta register, for example, a meta register that is selected by the latch input signal MS-WR, among the meta registers META REG in FIG. 4, based on the internal meta read pulse RGIO-ENP-MR.

FIG. 4 illustrates an example of the meta storage circuit 103.

As illustrated in FIG. 4, in an embodiment, the meta storage circuit 103 includes thirty-two meta registers META REG and eight metadata drivers METADATA DRV that are selected by first to fourth meta group signals MRG<0:3>. For example, the meta storage circuit 103 includes eight meta registers META REG and two metadata drivers METADATA DRV that are selected by the first meta group signal MRG<0>, eight meta registers META REG and two metadata drivers METADATA DRV that are selected by the second meta group signal MRG<1>, eight meta registers META REG and two metadata drivers METADATA DRV that are selected by the third meta group signal MRG<2>, and eight meta registers META REG and two metadata drivers METADATA DRV that are selected by the fourth meta group signal MRG<3>. The eight meta registers META REG that are selected by the first meta group signal MRG<0> are grouped into two sets of four meta registers META REG, and four meta registers META REG are allocated to each of the two metadata drivers METADATA DRV. 8 bits of metadata that are driven by the two metadata drivers METADATA DRV, four bits for each metadata driver METADATA DRV, may be stored in the eight meta registers META REG or may be output. The eight meta registers META REG that are selected by the second meta group signal MRG<1> are grouped into two sets of four meta registers META REG, and four meta registers META REG are allocated to each of the two metadata drivers METADATA DRV. 8 bits of metadata that are driven by the two metadata drivers METADATA DRV, four bits for each metadata driver METADATA DRV, may be stored in the eight meta registers META REG or may be output. The eight meta registers META REG that are selected by the third meta group signal MRG<2> are grouped into two sets of four meta registers META REG, and four meta registers META REG are allocated to each of the two metadata drivers METADATA DRV. 8 bits of metadata that are driven by the two metadata drivers METADATA DRV, four bits for each metadata driver METADATA DRV, may be stored in the eight meta registers META REG or may be output. The eight meta registers META REG that are selected by the second meta group signal MRG<3> are grouped into two sets of four meta registers META REG, and four meta registers META REG are allocated to each of the two metadata drivers METADATA DRV. 8 bits of metadata that are driven by the two metadata drivers METADATA DRV, four bits for each metadata driver METADATA DRV, may be stored in the eight meta registers META REG or may be output.

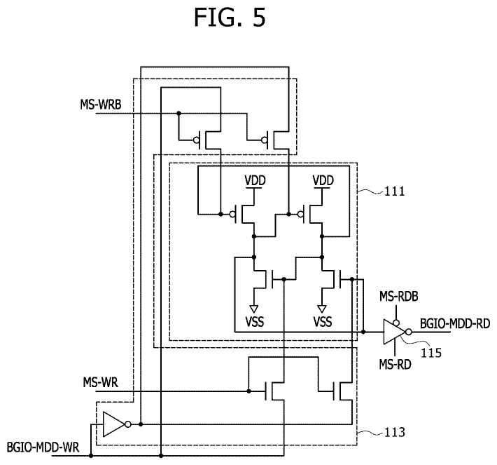

FIG. 5 illustrates a circuit of a meta register according to an example of the present disclosure.

As illustrated in FIG. 5, in an embodiment, the meta register includes a data latch 111, a latch input circuit 113, and a latch output circuit 115.

The latch input circuit 113 stores, in the data latch 111, metadata that are input through a write meta line BGIO-MDD-WR based on the latch input signal MS-WR that is generated at a logic high level and the inverted latch input signal MS-WRB that is generated at a logic low level when a meta write operation or an internal meta read operation is performed, for example.

The data latch 111 stores metadata that are received through the latch input circuit 113 when a meta write operation or an internal meta read operation is performed, for example. The data latch 111 may be implemented in a single latch type, for example, and stores 1 bit of metadata. The type of data latch 111 and the number of bits of metadata that are stored may be different than described in this example. The data latch 111 may be selected by the column address.

The latch output circuit 115 outputs metadata stored in the data latch 111 through a read meta line BGIO-MDD-RD based on the latch output signal MS-RD that is generated at a logic high level and an inverted latch output signal MS-RDB that is generated at a logic low level when a meta read operation or an internal meta write operation is performed, for example.

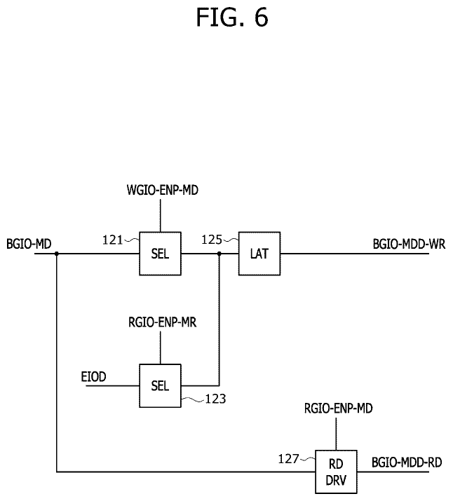

FIG. 6 illustrates a metadata driver according to an example of the present disclosure.

As illustrated in FIG. 6, in an embodiment, the metadata driver includes selectors SEL 121 and 123, a latch LAT 125, and a read driver RD DRV 127.

The selector 121 outputs metadata that are received through a meta line BGIO-MD based on the meta write pulse WGIO-ENP-MD that is generated when a meta write operation is performed. For example, when an internal meta read operation is performed, the selector 123 outputs metadata that are output by the memory cores and received through an internal line EIOD based on the internal meta read pulse RGIO-ENP-MR.

The latch 125 is electrically connected to the selectors 121 and 123, latches metadata that are output by the selectors 121 and 123, and outputs the latched metadata to a write meta line BGIO-MDD-WR. For example, when a meta write operation is performed, the latch 125 latches metadata that are output by the selector 121 and outputs the latched metadata to the write meta line BGIO-MDD-WR. For example, when an internal meta read operation is performed, the latch 125 latches metadata that are output by the selector 123 and outputs the latched metadata to the write meta line BGIO-MDD-WR.

The read driver 127 outputs, to the meta line BGIO-MD, metadata that are output by a meta register and received through a read meta line BGIO-MDD-RD based on the meta read pulse RGIO-ENP-MD when a meta read operation is performed.

When a meta write operation is performed, the metadata driver outputs metadata that are received through the meta line BGIO-MD to the write meta line BGIO-MDD-WR. When an internal meta read operation is performed, the metadata driver outputs, to the write meta line BGIO-MDD-WR, metadata that are output by a memory core and that are received through the internal line, such as internal line EIOD. When a meta read operation is performed, the metadata driver outputs, to the meta line BGIO-MD, metadata that are output by a meta register and that are received through the read meta line BGIO-MDD-RD.

FIG. 7 illustrates an input and output line driver according to an example of the present disclosure.

As illustrated in FIG. 7, in an embodiment, the input and output line driver includes selectors SEL 131 and 133, a latch LAT 135, and a read driver RD DRV 137.

The selector 131 outputs data that are received through an external line BGIO based on the write pulse WGIO-ENP that is generated when a meta write operation is performed. For example, when an internal meta write operation is performed, the selector 133 outputs metadata that are output by a meta register and that are received through the read meta line BGIO-MDD-RD based on the internal meta write pulse WGIO-ENP-MR.

The latch 135 is electrically connected to the selectors 131, 133, latches data that are output by the selector 131 and outputs the latched data to the internal line EIOD, and latches metadata that are output by the selector 133 and outputs the latched metadata to the internal line EIOD. For example, when a meta write operation is performed, the latch 135 latches data that are output by the selector 131 and outputs the latched data to the internal line EIOD. For example, when an internal meta write operation is performed, the latch 135 latches metadata that are output by the selector 133 and outputs the latched metadata to the internal line EIOD.

For example, when a meta read operation is performed, the read driver 137 outputs, to the external line BGIO, data that are output by a memory core and that are received through the internal line EIOD, based on the read pulse RGIO-ENP.

For example, when a meta write operation is performed, the input and output line driver outputs data that are received through the external line BGIO to the internal line EIOD. For example, when an internal meta write operation is performed, the input and output line driver outputs, to the internal line EIOD, metadata that are output by a meta register and that are received through the read meta line BGIO-MDD-RD. For example, when a meta read operation is performed, the input and output line driver outputs, to the external line BGIO, data that are output by a memory core and that are received through the internal line EIOD.

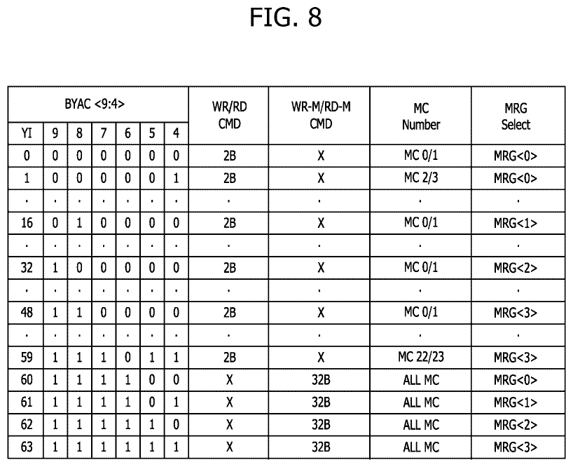

FIG. 8 illustrates a table including data utilized in a meta mode operation that is performed based on the column address according to an example of the present disclosure.

As illustrated in FIG. 8, when a meta write operation is performed during the state in which the column address BYAC<9:4> is a bit set “000000”, data totaling 32 bytes 32B or 256 bits are stored in the memory cores MC0 to MC31, 1 byte 1B or 8 bits in each memory core MC0 to MC31, and metadata totaling 2 bytes 2B or 16 bits are stored in the meta storage circuits META STG0/1 allocated to the memory cores MC0/1, 1 byte 1B or 8 bits in each meta storage circuit META STG0/1. Because the column selection signal YI0 for each of the memory cores MC0 to MC31 is selected based on the bit set “0000” of the column address BYAC<7:4>, data totaling 32 bytes 32B or 256 bits are stored in memory cells that belong to the memory cores MC0 to MC31 and that are accessed by the column selection signal YI0, 1 byte 1B or 8 bits for each memory core MC0 to MC31. Because the memory cores MC0/1 are selected based on the bit set “0000” of the column address BYAC<7:4> and the first meta group signal MRG<0> is selected based on the bit set “00” of the column address BYAC<9:8>, metadata totaling 16 bits is stored in meta registers that belong to each of the meta storage circuits META STG0/1, 8 bits stored in each meta storage circuit META STG0/1, allocated to the memory cores MC0/1 and that are selected by the first meta group signal MRG<0>.

As illustrated in FIG. 8, when a meta read operation is performed in the state in which the column address BYAC<9:4> is the bit set “000000”, 1 byte 1B or 8 bits of data (data totaling 32 bytes 32B or 256 bits) stored in each of the memory cores MC0 to MC31 may be output, and 1 byte 1B or 8 bits of metadata (metadata totaling 2 bytes 2B or 16 bits) stored in each of the meta storage circuits META STG0/1 allocated to the memory cores MC0/1 may be output. Because the column selection signal YI0 for each of the memory cores MC0 to MC31 is selected based on the bit set “0000” of the column address BYAC<7:4>, 1 byte 1B or 8 bits of data (data totaling 32 bytes 32B or 256 bits) stored in each of memory cells that belong to the memory cores MC0 to MC31 and that are accessed by the column selection signal YI0 may be output. Because the memory cores MC0/1 are selected based on the bit set “0000” of the column address BYAC<7:4>, and the first meta group signal MRG<0> is selected based on the bit set “00” of the column address BYAC<9:8>, metadata totaling 2 bytes 2B or 16 bits stored in meta registers, 8 bits that belong to each of the meta storage circuits META STG0/1 allocated to the memory cores MC0/1 and that are selected by the first meta group signal MRG<0>, may be output.

As illustrated in FIG. 8, when a meta write operation is performed in the state in which the column address BYAC<9:4> is bit set “000001”, data totaling 32 bytes 32B or 256 bits may be stored in the memory cores MC0 to MC31, 1 byte 1B or 8 bits for each memory core MC0 to MC31, and metadata totaling 2 bytes 2B or 16 bits are stored in the meta storage circuits META STG2/3 allocated to the memory cores MC2/3, 1 byte 1B or 8 bits for each meta storage circuits META STG2/3. Because the column selection signal YI1 for each of the memory cores MC0 to MC31 is selected based on the bit set “0001” of the column address BYAC<7:4>, data totaling 32 bytes 32B or 256 bits, 1 byte 1B or 8 bits for each memory core MC0 to MC31, may be stored in memory cells that belong to the memory cores MC0 to MC31 and that are accessed by the column selection signal YI1. Because the memory cores MC2/3 are selected based on the bit set “0001” of the column address BYAC<7:4>, and the first meta group signal MRG<0> is selected based on the bit set “00” of the column address BYAC<9:8>, metadata totaling 2 bytes 2B or 16 bits, 8 bits for each meta storage circuits META STG2/3, may be stored in meta registers that belong to each of the meta storage circuits META STG2/3 allocated to the memory cores MC2/3 and that are selected by the first meta group signal MRG<0>.

As illustrated in FIG. 8, when a meta read operation is performed in the state in which the column address BYAC<9:4> is a bit set “000001”, 1 byte 1B or 8 bits of data (data totaling 32 bytes 32B or 256 bits) stored in each of the memory cores MC0 to MC31 may be output, and 1 byte 1B or 8 bits of metadata (metadata totaling 2 bytes 2B or 16 bits) stored in each of the meta storage circuits META STG0/1 allocated to the memory cores MC2/3 may be output. Because the column selection signal YI16 for each of the memory cores MC0 to MC31 is selected based on the bit set “0001” of the column address BYAC<7:4>, 1 byte 1B or 8 bits of data (data totaling 32 bytes 32B or 256 bits) stored in each of memory cells that belong to the memory cores MC0 to MC31 and that are accessed by the column selection signal YI1 may be output. Because the memory cores MC2/3 are selected based on the bit set “0001” of the column address BYAC<7:4> and the first meta group signal MRG<0> is selected based on the bit set “00” of the column address BYAC<9:8>, metadata totaling 2 bytes 2B or 16 bits stored in meta registers, 8 bits that belong to each of the meta storage circuits META STG2/3 allocated to the memory cores MC2/3 and that are selected by the first meta group signal MRG<0>, may be output.

As illustrated in FIG. 8, when a meta write operation is performed in the state in which the column address BYAC<9:4> is bit set “010000”, data totaling 32 bytes 32B or 256 bits may be stored in the memory cores MC0 to MC31, 1 byte 1B or 8 bits for each memory core MC0 to MC31, and metadata totaling 2 bytes 2B or 16 bits may be stored in the meta storage circuits META STG0/1 allocated to the memory cores MC0/1, 1 byte 1B or 8 bits for each meta storage circuit META STG0/1. Because the column selection signal YI1 for each of the memory cores MC0 to MC31 6 is selected based on the bit set “0000” of the column address BYAC<7:4>, data totaling 32 bytes 32B or 256 bits, 1 byte 1B or 8 bits for each memory core MC0 to MC31, may be stored in memory cells that belong to the memory cores MC0 to MC31 and that are accessed by the column selection signal YI16. Because the memory cores MC0/1 are selected based on the bit set “0000” of the column address BYAC<7:4>, and the second meta group signal MRG<1> is selected based on the bit set “01” of the column address BYAC<9:8>, metadata totaling 2 bytes 2B or 16 bits, 8 bits for each meta storage circuits META STG0/1, may be stored in meta registers that belong to each of the meta storage circuits META STG0/1 allocated to the memory cores MC0/1 and that are selected by the second meta group signal MRG<1>.

As illustrated in FIG. 8, when a meta read operation is performed in the state in which the column address BYAC<9:4> has is bit set “010000”, 1 byte 1B or 8 bits of data (data totaling 32 bytes 32B or 256 bits) stored in each of the memory cores MC0 to MC31 may be output, and 1 byte 1B or 8 bits of metadata (metadata totaling 2 bytes 2B or 16 bits) stored in each of the meta storage circuits META STG0/1 allocated to the memory cores MC0/1 may be output. Because the column selection signal YI1 for each of the memory cores MC0 to MC31 6 is selected based on the bit set “0000” of the column address BYAC<7:4>, 1 byte 1B or 8 bits of data (data totaling 32 bytes 32B or 256 bits) stored in each of memory cells that belong to the memory cores MC0 to MC31 and that are accessed by the column selection signal YI16 may be output. Because the memory cores MC0/1 are selected based on the bit set “0000” of the column address BYAC<7:4>, and the second meta group signal MRG<1> is selected based on the bit set “01” of the column address BYAC<9:8>, metadata totaling 2 bytes 2B or 16 bits stored in meta registers, 8 bits that belong to each of the meta storage circuits META STG0/1 allocated to the memory cores MC0/1 and that are selected by the second meta group signal MRG<1>, may be output.

As illustrated in FIG. 8, when a meta write operation is performed in the state in which the column address BYAC<9:4> is bit set “100000”, data totaling 32 bytes 32B or 256 bits may be stored in the memory cores MC0 to MC31, 1 byte 1B or 8 bits for each memory core MC0 to MC31, and metadata totaling 2 bytes 2B or 16 bits are stored in the meta storage circuits META STG0/1 allocated to the memory cores MC0/1, 1 byte 1B or 8 bits for each meta storage circuit META STG0/1. Because the column selection signal YI32 for each of the memory cores MC0 to MC31 is selected based on the bit set “0000” of the column address BYAC<7:4>, data totaling 32 bytes 32B or 256 bits, 1 byte 1B or 8 bits for each memory core MC0 to MC31, may be stored in memory cells that belong to the memory cores MC0 to MC31 and that are accessed by the column selection signal YI32. Because the memory cores MC0/1 are selected based on the bit set “0000” of the column address BYAC<7:4>, and the third meta group signal MRG<2> is selected based on the bit set “10” of the column address BYAC<9:8>, metadata totaling 2 bytes 2B or 16 bits, 8 bits for each meta storage circuits META STG0/1, may be stored in meta registers that belong to each of the meta storage circuits META STG0/1 allocated to the memory cores MC0/1 and that are selected by the third meta group signal MRG<2>.

As illustrated in FIG. 8, when a meta read operation is performed in the state in which the column address BYAC<9:4> is bit set “100000”, 1 byte 1B or 8 bits of data (data totaling 32 bytes 32B or 256 bits) stored in each of the memory cores MC0 to MC31 may be output, and 1 byte 1B or 8 bits of metadata (metadata totaling 2 bytes 2B or 16 bits) stored in each of the meta storage circuits META STG0/1 allocated to the memory cores MC0/1 may be output. Because the column selection signal YI32 for each of the memory cores MC0 to MC31 is selected based on the bit set “0000” of the column address BYAC<7:4>, 1 byte 1B or 8 bits of data (data totaling 32 bytes 32B or 256 bits) stored in each of memory cells that belong to the memory cores MC0 to MC31 and that are accessed by the column selection signal YI32 may be output. Because the memory cores MC0/1 are selected based on the bit set “0000” of the column address BYAC<7:4>, and the third meta group signal MRG<2> is selected based on the bit set “10” of the column address BYAC<9:8>, metadata totaling 2 bytes 2B or 16 bits stored in meta registers, 8 bits that belong to each of the meta storage circuits META STG0/1 allocated to the memory cores MC0/1 and that are selected by the third meta group signal MRG<2>, may be output.

As illustrated in FIG. 8, when a meta write operation is performed in the state in which the column address BYAC<9:4> is bit set “110000”, data totaling 32 bytes 32B or 256 bits may be stored in the memory cores MC0 to MC31, 1 byte 1B or 8 bits for each memory core MC0 to MC31, and metadata totaling 2 bytes 2B or 16 bits may be stored in the meta storage circuits META STG0/1 allocated to the memory cores MC0/1, 1 byte 1B or 8 bits for each meta storage circuit META STG0/1. Because the column selection signal YI48 for each of the memory cores MC0 to MC31 is selected based on the bit set “0000” of the column address BYAC<7:4>, data totaling 32 bytes 32B or 256 bits, 1 byte 1B or 8 bits for each memory core MC0 to MC31 may be stored in memory cells that belong to the memory cores MC0 to MC31 and that are accessed by the column selection signal YI48. Because the memory cores MC0/1 are selected based on the bit set “0000” of the column address BYAC<7:4>, and the fourth meta group signal MRG<3> is selected based on the bit set “11” of the column address BYAC<9:8>, metadata totaling 2 bytes 2B or 16 bits, 8 bits for each meta storage circuits META STG0/1, may be stored in meta registers that belong to each of the meta storage circuits META STG0/1 allocated to the memory cores MC0/1 and that are selected by the fourth meta group signal MRG<3>.

As illustrated in FIG. 8, when a meta read operation is performed in the state in which the column address BYAC<9:4> is bit set “110000”, 1 byte 1B or 8 bits of data (data totaling 32 bytes 32B or 256 bits) stored in each of the memory cores MC0 to MC31 may be output, and 1 byte 1B or 8 bits of metadata (metadata totaling 2 bytes 2B or 16 bits) stored in each of the meta storage circuits META STG0/1 allocated to the memory cores MC0/1 may be output. Because the column selection signal YI48 for each of the memory cores MC0 to MC31 is selected based on the bit set “0000” of the column address BYAC<7:4>, 1 byte 1B or 8 bits of data (data totaling 32 bytes 32B or 256 bits) stored in each of the memory cells that belong to the memory cores MC0 to MC31 and that are accessed by the column selection signal YI48 may be output. Because the memory cores MC0/1 are selected based on the bit set “0000” of the column address BYAC<7:4>, and the fourth meta group signal MRG<3> is selected based on the bit set “11” of the column address BYAC<9:8>, metadata totaling 2 bytes 2B or 16 bits stored in meta registers, 8 bits that belong to each of the meta storage circuits META STG0/1 allocated to the memory cores MC0/1 and that are selected by the fourth meta group signal MRG<3>, may be output.

As illustrated in FIG. 8, when an internal meta write operation is performed in the state in which the column address BYAC<9:4> is bit set “111011”, data totaling 32 bytes 32B or 256 bits may be stored in the memory cores MC0 to MC31, 1 byte 1B or 8 bits for each memory core MC0 to MC31, and metadata totaling 2 bytes 2B or 16 bits may be stored in the meta storage circuits META STG22/23 allocated to the memory cores MC22/23, 1 byte 1B or 8 bits for each meta storage circuit META STG22/23. Because the column selection signal YI59 for each of the memory cores MC0 to MC31 is selected based on the bit set “1011” of the column address BYAC<7:4>, data totaling 32 bytes 32B or 256 bits, 1 byte 1B or 8 bits for each memory core MC0 to MC31 may be stored in memory cells that belong to the memory cores MC0 to MC31 and that are accessed by the column selection signal YI59. Because the memory cores MC22/23 are selected based on the bit set “1011” of the column address BYAC<7:4> and the fourth meta group signal MRG<3> is selected based on the bit set “11” of the column address BYAC<9:8>, metadata totaling 2 bytes 2B or 16 bits, 8 bits for each meta storage circuits META STG22/23, may be stored in meta registers that belong to each of the meta storage circuits META STG22/23 allocated to the memory cores MC22/23 and that are selected by the fourth meta group signal MRG<3>.

As illustrated in FIG. 8, when a meta read operation is performed in the state in which the column address BYAC<9:4> is bit set “111011”, 1 byte 1B or 8 bits of data (data totaling 32 bytes 32B or 256 bits) stored in each of the memory cores MC0 to MC31 may be output, and 1 byte 1B or 8 bits of metadata (metadata totaling 2 bytes 2B or 16 bits) stored in each of the meta storage circuits META STG22/23 allocated to the memory cores MC22/23 may be output. Because the column selection signal YI59 for each of the memory cores MC0 to MC31 is selected based on the bit set “1011” of the column address BYAC<7:4>, 1 byte 1B or 8 bits of data (data totaling 32 bytes 32B or 256 bits) stored in each of memory cells that belong to the memory cores MC0 to MC31 and that are accessed by the column selection signal YI59 may be output. Because the memory cores MC22/23 are selected based on the bit set “1011” of the column address BYAC<7:4>, and the fourth meta group signal MRG<3> is selected based on the bit set “11” of the column address BYAC<9:8>, metadata totaling 2 bytes 2B or 16 bits stored in meta registers, 8 bits that belong to each of the meta storage circuits META STG22/23 allocated to the memory cores MC22/23 and that are selected by the fourth meta group signal MRG<3>, may be output.

As illustrated in FIG. 8, when an internal meta write operation is performed in the state in which the column address BYAC<9:4> is bit set “111100”, 1 byte 1B or 8 bits of data (data totaling 32 bytes 32B or 256 bits) stored in each of the meta storage circuits META STG0 to META STG31 may be output, and the data totaling 32 bytes 32B may be stored in the memory cores MC0 to MC31. Because the memory cores MC0 to MC31 and the meta storage circuits META STG0 to META STG31 are selected based on the bit set “1111” of the column address BYAC<9:6>, and the first meta group signal MRG<0> and the column selection signal YI60 are selected based on the bit set “00” of the column address BYAC<5:4>, metadata totaling 32 bytes 32B or 256 bits stored in meta registers, 8 bits that belong to each of the meta storage circuits META STG0 to META STG31 and that are selected by the first meta group signal MRG<0>, may be output and stored in memory cells that belong to the memory cores MC0 to MC31 and that are accessed by the column selection signal YI60.

As illustrated in FIG. 8, when an internal meta read operation is performed in the state in which the column address BYAC<9:4> is bit set “111100”, 1 byte 1B or 8 bits of data (data totaling 32 bytes 32B or 256 bits) stored in each of the memory cores MC0 to MC31 may be output, and the data totaling 32 bytes 32B may be stored in the meta storage circuits META STG0 to META STG31. Because the memory cores MC0 to MC31 and the meta storage circuits META STG0 to META STG31 are selected based on the bit set “1111” of the column address BYAC<9:6>, and the first meta group signal MRG<0> and the column selection signal YI60 are selected based on the bit set “00” of the column address BYAC<5:4>, 1 byte 1B or 8 bits of metadata) (metadata totaling 32 bytes 32B or 256 bits) stored in each of memory cells that belong to each of the memory cores MC0 to MC31 and that are accessed by the column selection signal YI60 may be output, and the metadata totaling 32 bytes 32B may be stored in meta registers that belong to each of the meta storage circuits META STG0 to META STG31 and that are selected by the first meta group signal MRG<0>.

As illustrated in FIG. 8, when an internal meta write operation is performed in the state in which the column address BYAC<9:4> is bit set “111101”, 1 byte 1B or 8 bits of metadata (metadata totaling 32 bytes 32B or 256 bits) stored in each of the meta storage circuits META STG0 to META STG31 may be output, and the metadata totaling 32 bytes 32B may be stored in the memory cores MC0 to MC31. Because the memory cores MC0 to MC31 and the meta storage circuits META STG0 to META STG31 are selected based on the bit set “1111” of the column address BYAC<9:6> and the second meta group signal MRG<1> and the column selection signal YI61 are selected based on the bit set “01” of the column address BYAC<5:4>, metadata totaling 32 bytes 32B or 256 bits stored in meta registers, 8 bits that belong to each of the meta storage circuits META STG0 to META STG31 and that are selected by the second meta group signal MRG<1>, may be output and stored in memory cells that belong to each of the memory cores MC0 to MC31 and that are accessed by the column selection signal YI61.

As illustrated in FIG. 8, when an internal meta read operation is performed in the state in which the column address BYAC<9:4> is bit set “111101”, 1 byte 1B or 8 bits of metadata (metadata totaling 32 bytes 32B or 256 bits) stored in each of the memory cores MC0 to MC31 may be output, and the metadata totaling 32 bytes may be stored in the meta storage circuits META STG0 to META STG31. Because the memory cores MC0 to MC31 and the meta storage circuits META STG0 to META STG31 are selected based on the bit set “1111” of the column address BYAC<9:6> and the second meta group signal MRG<1> and the column selection signal YI61 are selected based on the bit set “01” of the column address BYAC<5:4>, 1 byte 1B or 8 bits of metadata (metadata totaling 32 bytes 32B or 256 bits) stored in each of memory cells that belong to each of the memory cores MC0 to MC31 and that are accessed by the column selection signal YI61 may be output, and the metadata totaling 32 bytes (32B) may be stored meta registers that belong to each of the meta storage circuits META STG0 to META STG31 and that are selected by the second meta group signal MRG<1>.

As illustrated in FIG. 8, when an internal meta write operation is performed in the state in which the column address BYAC<9:4> is bit set “111110”, 1 byte 1B or 8 bits of metadata (metadata totaling 32 bytes 32B or 256 bits) stored in each of the meta storage circuits META STG0 to META STG31 may be output, and the metadata totaling 32 bytes 32B may be stored in the memory cores MC0 to MC31. Because the memory cores MC0 to MC31 and the meta storage circuits META STG0 to META STG31 are selected based on the bit set “1111” of the column address BYAC<9:6>, and the third meta group signal MRG<2> and the column selection signal YI62 are selected based on the bit set “10” of the column address BYAC<5:4>, metadata totaling 32 bytes 32B or 256 bits stored in meta registers, 8 bits that belong to each of the meta storage circuits META STG0 to META STG31 and that are selected by the third meta group signal MRG<2>, may be output and stored in memory cells that belong to the memory cores MC0 to MC31 and that are selected by the column selection signal YI62.

As illustrated in FIG. 8, when an internal meta read operation is performed in the state in which the column address BYAC<9:4> is bit set “111110”, 1 byte 1B or 8 bits of metadata (metadata totaling 32 bytes 32B or 256 bits) stored in each of the memory cores MC0 to MC31 may be output, and the metadata totaling 32 bytes 32B may be stored in the meta storage circuits META STG0 to META STG31. Because the memory cores MC0 to MC31 and the meta storage circuits META STG0 to META STG31 are selected based on the bit set “1111” of the column address BYAC<9:6>, and the third meta group signal MRG<2> and the column selection signal YI62 are selected based on the bit set “10” of the column address BYAC<5:4>, 1 byte 1B or 8 bits of metadata (metadata totaling 32 bytes 32B or 256 bits) stored in memory cells that belong to each of the memory cores MC0 to MC31 and that are selected by the column selection signal YI62 may be output, and the metadata totaling 32 bytes 32B may be stored in meta registers that belong to each of the meta storage circuits META STG0 to META STG31 and that are selected by the third meta group signal MRG<2>.

As illustrated in FIG. 8, when an internal meta write operation is performed in the state in which the column address BYAC<9:4> is bit set “111111”, 1 byte 1B or 8 bits of metadata (metadata totaling 32 bytes 32B or 256 bits) stored in each of the meta storage circuits META STG0 to META STG31 may be output, and the metadata totaling 32 bytes 32B may be stored in the memory cores MC0 to MC31. Because the memory cores MC0 to MC31 and the meta storage circuits META STG0 to META STG31 are selected based on the bit set “1111” of the column address BYAC<9:6>, and the fourth meta group signal MRG<3> and the column selection signal YI63 are selected based on the bit set “11” of the column address BYAC<5:4>, metadata totaling 32 bytes 32B or 256 bits stored in meta registers, 8 bits that belong to each of the meta storage circuits META STG0 to META STG31 and that are selected the fourth meta group signal MRG<3>, may be output by 8 bits and stored in memory cells that belong to the memory cores MC0 to MC31 and that are accessed by the column selection signal YI63.

As illustrated in FIG. 8, when an internal meta read operation is performed in the state in which the column address BYAC<9:4> is bit set “111111”, 1 byte 1B or 8 bits of metadata (metadata totaling 32 bytes 32B or 256 bits) stored in each of the memory cores MC0 to MC31 may be output, and the metadata totaling 32 bytes 32B may be stored in the meta storage circuits META STG0 to META STG31. Because the memory cores MC0 to MC31 and the meta storage circuits META STG0 to META STG31 are selected based on the bit set “1111” of the column address BYAC<9:6>, and the fourth meta group signal MRG<3> and the column selection signal YI63 are selected based on the bit set “11” of the column address BYAC<5:4>, 1 byte 1B or 8 bits of metadata (metadata totaling 32 bytes 32B or 256 bits) stored in each of memory cells that belong to each of the memory cores MC0 to MC31 and that are selected by the column selection signal YI62 may be output, and the metadata totaling 32 bytes 32B may be stored in meta registers that belong to each of the meta storage circuits META STG0 to META STG31 and that are selected by the fourth meta group signal MRG<3>.

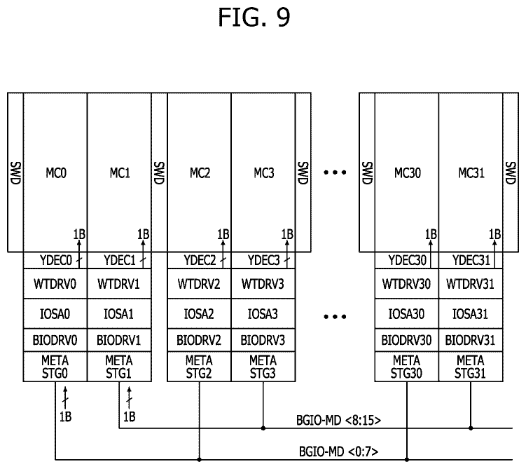

FIG. 9 illustrates a memory device during an operation including storing data and metadata during a meta write operation. As illustrated in FIG. 9, when a meta write operation is performed in the state in which the column selection signal YI0 is selected in each of the column decoders YDEC0 to YDEC31 based on the column address BYAC, data totaling 32 bytes 32B or 256 bits may be stored in the memory cores MC0 to MC31 by 1 byte 1B or 8 bits. When a meta write operation is performed in the state in which the memory cores MC0/1 are selected by the column address BYAC, metadata totaling 2 bytes 2B or 16 bits may be stored in the meta storage circuits META STG0/1, 1 byte 1B or 8 bits for each meta storage circuit META STG0/1.

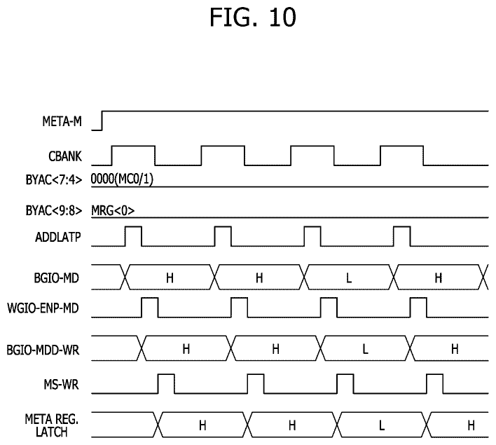

FIG. 10 illustrates a timing diagram during a meta write operation including storing metadata based on the column address BYAC<9:4>. As illustrated in FIG. 10, for example, when the column bank signals CBANK are sequentially generated while a meta write operation is performed, the column address BYAC<9:4> is latched based on the address latch pulse ADDLATP. Because the memory cores MC0/1 are selected based on the bit set “0000” of the column address BYAC<7:4>, and the first meta group signal MRG<0> is selected based on the bit set “00” of the column address BYAC<9:8>, metadata are stored in meta registers of the meta storage circuits META STG0/1 corresponding to the memory cores MC0/1, for example. Metadata at logic levels “H”, “H”, “L”, “H” and that are sequentially input through the meta line BGIO-MD in synchronization with the meta write pulse WGIO-ENP-MD are output to the write meta line BGIO-MDD-WR, for example. Furthermore, metadata at logic levels “H”, “H”, “L”, “H” and that are input through the write meta line BGIO-MDD-WR in synchronization with the latch input signal MS-WR are stored in meta registers that belong to the meta storage circuits META STG0/1 and that are selected by the first meta group signal MRG<0>, for example.

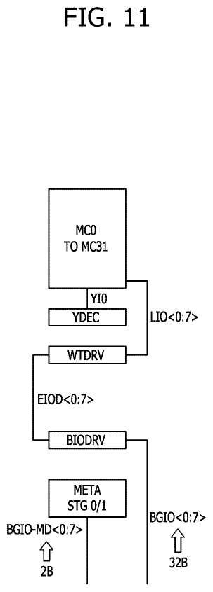

FIG. 11 illustrates a path along which data and metadata are stored during a meta write operation in a memory device. As illustrated in FIG. 10 and FIG. 11, because the memory cores MC0/1 are selected based on the bit set “0000” of the column address BYAC<7:4>, and the first meta group signal MRG<0> is selected based on the bit set “00” of the column address BYAC<9:8>, metadata totaling 2 bytes 2B or 16 bits that are received through the meta line BGIO-MD are stored in meta registers that belong to each of the meta storage circuits META STG0/1 allocated to the memory cores MC0/1 and that are selected by the first meta group signal MRG<0>, for example. Because the column selection signal YI0 for each of the memory cores MC0 to MC31 is selected in the column decoder YDEC based on the bit set “0000” of the column address BYAC<7:4>, data totaling 32 bytes 32B or 256 bits that are received through the external line BGIO<0:7> are sequentially transmitted to the internal lines EIOD<0:7> and the local lines LIO<0:7> through the input and output line driver BIODRV and the write driver WTDRV and are stored in memory cells that belong to each of the memory cores MC0 to MC31 and that are accessed by the column selection signal YI0 that is selected through the column decoder YDEC. Although the memory cores MC0 to MC31, the column decoder YDEC, the input and output line driver BIODRV, and the write driver WTDRV are represented as one block in FIG. 11, the column decoder YDEC, the input and output line driver BIODRV, and the write driver WTDRV may be separate components for each of the memory cores MC0 to MC31. Although the meta storage circuits META STG0/1 are represented as one block in FIG. 11, the meta storage circuits META STG0/1 may be separate meta storage circuits META STG0/1.

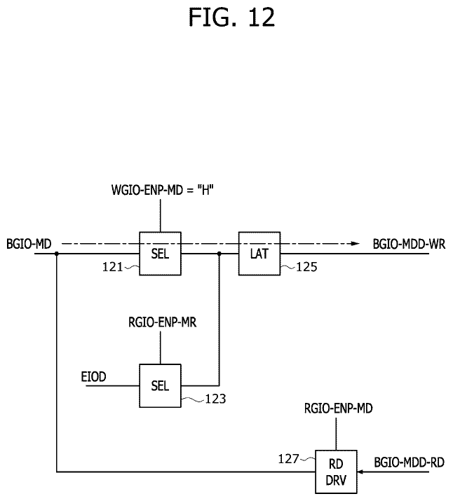

FIG. 12 illustrates a metadata driver during a meta write operation including outputting received metadata to the write meta line BGIO-MDD-WR as shown by the dashed line. As illustrated in FIG. 12, while the meta write pulse WGIO-ENP-MD is generated at a logic high level “H” when a meta write operation is performed, for example, metadata that are received through the meta line BGIO-MD are stored in the latch 125 through the selector 121. The metadata that are stored in the latch 125 are output to the write meta line BGIO-MDD-WR.

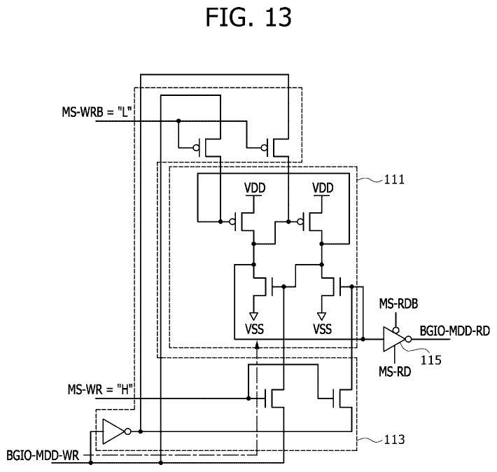

FIG. 13 illustrates a circuit of a meta register during a meta write operation including storing metadata, received through the write meta line BGIO-MDD-WR, in the data latch 111 as shown by the dashed line. As illustrated in FIG. 13, for example, when a meta write operation is performed, while the latch input signal MS-WR is generated at a logic high level “H” and the inverted latch input signal MS-WRB is generated at a logic low level “L”, metadata that are received through the write meta line BGIO-MDD-WR are stored in the data latch 111.

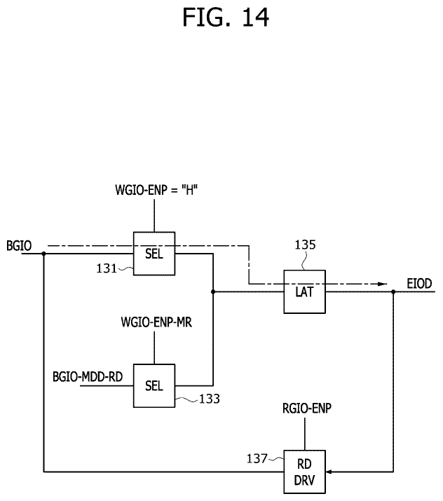

FIG. 14 illustrates an input and output line driver during a meta write operation including outputting received data to the internal line EIOD as shown by the dashed line. As illustrated in FIG. 14, for example, while the write pulse WGIO-ENP is generated at a logic high level “H” when a meta write operation is performed, data that are received through the external line BGIO are stored in the latch 135 through the selector 131. The metadata that are stored in the latch 135 are output to the internal line EIOD.

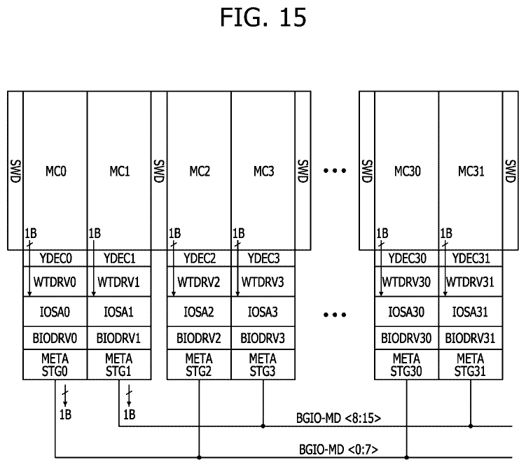

FIG. 15 illustrates a memory device during a meta read operation including output of data and metadata. As illustrated in FIG. 15, when a meta read operation is performed in the state in which the column selection signal YI0 is selected in the column decoders YDEC0 to YDEC31 based on the column address BYAC, 1 byte 1B or 8 bits of data (data totaling 32 bytes 32B or 256 bits) stored in each of the memory cores MC0 to MC31 may be output. When a meta read operation is performed in the state in which the memory cores MC0/1 are selected by the column address BYAC, 1 byte 1B or 8 bits of metadata (metadata totaling 2 bytes 2B or 16 bits) stored in each of the meta storage circuits META STG0/1 may be output.

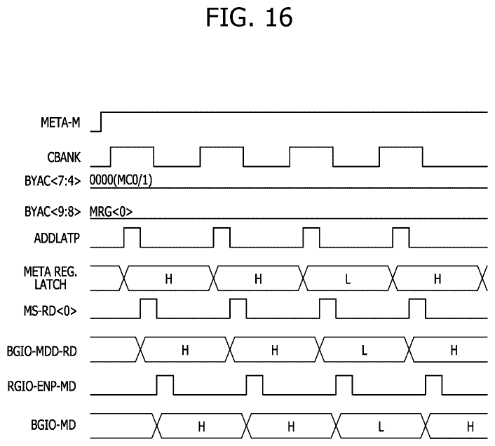

FIG. 16 illustrates a timing diagram during a meta read operation including output of metadata stored in the meta registers based on the column address BYAC<9:4>. As illustrated in FIG. 16, for example, when the column bank signals CBANK are sequentially generated while a meta read operation is performed, the column address BYAC<9:4> is latched based on the address latch pulse ADDLATP. For example, because the memory cores MC0/1 are selected based on the bit set “0000” of the column address BYAC<7:4>, and the first meta group signal MRG<0> is selected based on the bit set “00” of the column address BYAC<9:8>, metadata stored in meta registers of the meta storage circuits META STG0/1 corresponding to the memory cores MC0/1 are output to the read meta line BGIO-MDD-RD. More specifically, for example, metadata at logic levels “H”, “H”, “L”, “H” and that are stored in meta registers, which belong to the meta storage circuits META STG0/1 and are selected by the first meta group signal MRG<0> in synchronization with the latch output signal MS-RD, are output to the read meta line BGIO-MDD-RD. For example, metadata at logic levels “H”, “H”, “L”, “H” and that are sequentially input through the read meta line BGIO-MDD-RD in synchronization with the meta read pulse RGIO-ENP-MD are output to the meta line BGIO-MD.

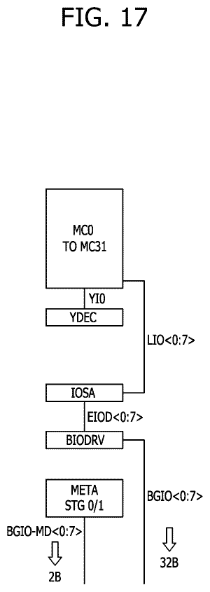

FIG. 17 illustrates a path along which data and metadata are output during a meta read operation in a memory device. As illustrated in FIG. 16 and FIG. 17, for example, because the memory cores MC0/1 are selected based on the bit set “0000” of the column address BYAC<7:4>, and the first meta group signal MRG<0> is selected based on the bit set “00” of the column address BYAC<9:8>, metadata totaling 2 bytes 2B or 16 bits stored in meta registers, which belong to each of the meta storage circuits META STG0/1 allocated to the memory cores MC0/1 and are selected by the first meta group signal MRG<0>, are output to the meta line BGIO-MD<0:7>. For example, because the column selection signal YI0 for each of the memory cores MC0 to MC31 is selected based on the bit set “0000” of the column address BYAC<7:4>, 1 byte 1B or 8 bits of data (data totaling 32 bytes 32B or 256 bits) stored in each of the memory cores MC0 to MC31 are output to the local lines LIO<0:7>. The data totaling 32 bytes 32B or 256 bits that are output to the local lines LIO<0:7> are sequentially output to the internal lines EIOD<0:7> and the external line BGIO<0:7> through the input and output sense amplifiers IOSA and the input and output line driver BIODRV. Although the memory cores MC0 to MC31, the column decoder YDEC, the input and output sense amplifiers IOSA, and the input and output line driver BIODRV are represented as one block in FIG. 17, the column decoder YDEC, the input and output sense amplifiers IOSA, and the input and output line driver BIODRV may be separate components for each of the memory cores MC0 to MC31. Although the meta storage circuits META STG0/1 are represented as one block in FIG. 11, the meta storage circuits META STG0/1 may be separate meta storage circuits META STG0/1.

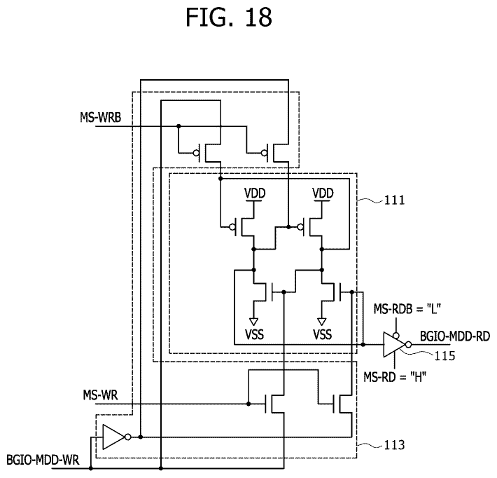

FIG. 18 illustrates a circuit of a meta register during a meta read operation including output to the read meta line BGIO-MDD-RD of metadata stored in the data latch 111. As illustrated in FIG. 18, for example, when a meta read operation is performed, while the latch output signal MS-RD is generated at a logic high level “H” and the inverted latch output signal MS-RDB is generated at a logic low level “L”, metadata stored in the data latch 111 are output to the read meta line BGIO-MDD-RD.

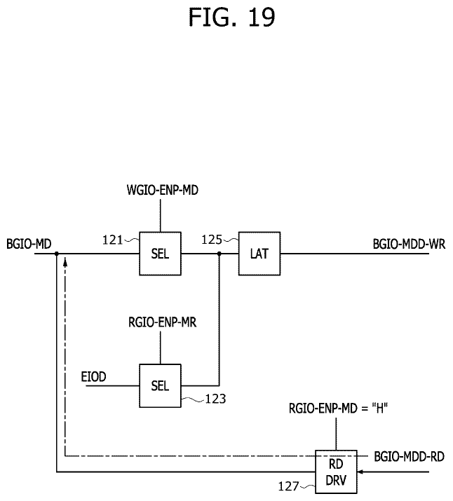

FIG. 19 illustrates a metadata driver during an operation including output to the meta line BGIO-MD of metadata that are received through the read meta line BGIO-MDD-RD as shown by the dashed line. As illustrated in FIG. 19, for example, while the meta read pulse RGIO-ENP-MD is generated at a logic high level “H” when a meta read operation is performed, metadata that are received through the read meta line BGIO-MDD-RD are output to the meta line BGIO-MD through the read driver 127.

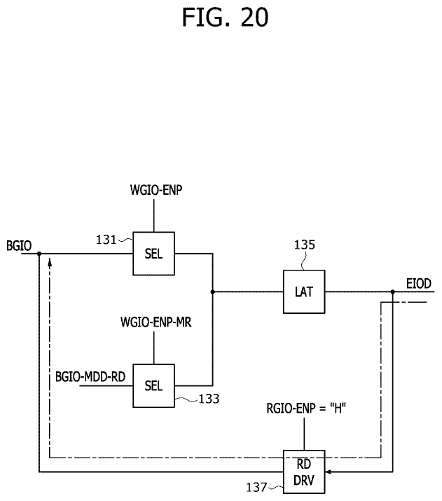

FIG. 20 illustrates an input and output line driver during a meta read operation including output to the external line BGIO of data that are received through the internal line EIOD as shown by the dashed line. As illustrated in FIG. 20, for example, while the read pulse RGIO-ENP is generated at a logic high level “H” when a meta read operation is performed, data that are received through the internal line EIOD are output to the external line BGIO through the read driver 137.

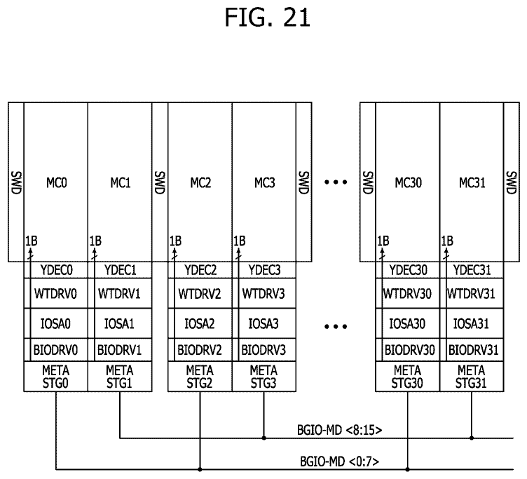

FIG. 21 illustrates a memory device during an internal meta write operation including storing metadata that are output by the meta storage circuits in the memory cores. As illustrated in FIG. 21, 1 byte 1B or 8 bits of metadata (metadata totaling 32 bytes 32B or 256 bits) stored in each of the meta storage circuits META STG0 to META STG31 may be output and stored in each of the memory cores MC0 to MC31 based on the column address BYAC.

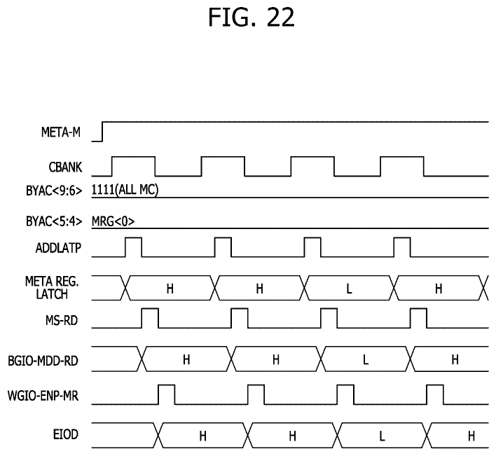

FIG. 22 illustrates a timing diagram during an internal meta write operation including outputting and storing metadata based on the column address BYAC<9:4>. As illustrated in FIG. 22, for example, when the column bank signals CBANK are sequentially generated while an internal meta write operation is performed, the column address BYAC<9:4> is latched based on the address latch pulse ADDLATP. Because the memory cores MC0 to MC31 and the meta storage circuits META STG0 to META STG31 are selected based on the bit set “1111” of the column address BYAC<9:6>, and the first meta group signal MRG<0> and the column selection signal YI60 are selected based on the bit set “00” of the column address BYAC<5:4>, metadata at logic levels “H”, “H”, “L”, “H” and that are stored in meta registers that belong to each of the meta storage circuits META STG0 to META STG31 and that are selected by the first meta group signal MRG<0> are output to the read meta line BGIO-MDD-RD in synchronization with the latch output signal MS-RD. Metadata at logic levels “H”, “H”, “L”, “H” and that are received through the read meta line BGIO-MDD-RD when the internal meta write pulse WGIO-ENP-MR is generated are output to the internal line EIOD and stored in memory cells that belong to the memory cores MC0 to MC31 and that are accessed by the column selection signal YI60.

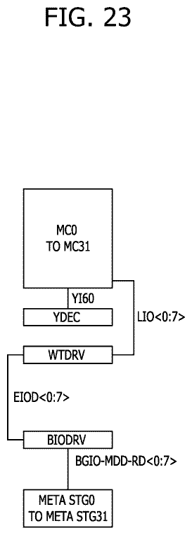

FIG. 23 illustrates a path along which metadata are output from the meta storage circuits and a path along which metadata are stored in the memory cores during an internal meta write operation in a memory device. As illustrated in FIG. 22 and FIG. 23, because the memory cores MC0 to MC31 and the meta storage circuits META STG0 to META STG31 are selected based on the bit set “1111” of the column address BYAC<9:6>, and the first meta group signal MRG<0> and the column selection signal YI60 are selected based on the bit set “00” of the column address BYAC<5:4>, metadata stored in meta registers that belong to each of the meta storage circuits META STG0 to META STG31 and that are selected by the first meta group signal MRG<0> are output to the read meta line BGIO-MDD-RD through the input and output driver BIODRV. The metadata that are output to the read meta line BGIO-MDD-RD are sequentially transmitted to the internal lines EIOD<0:7> and the local lines LIO<0:7> through the input and output line driver BIODRV and the write driver WTDRV and are stored in memory cells that belong to each of the memory cores MC0 to MC31 and that are accessed by the column selection signal YI60 that is selected through the column decoder YDEC. Although the memory cores MC0 to MC31, the column decoder YDEC, the write driver WTDRV, the input and output line driver BIODRV, and the meta storage circuits META STG0 to META STG31 are represented as one block in FIG. 23, the column decoder YDEC, the write driver WTDRV, and the input and output line driver BIODRV may be separate components for each of the memory cores MC0 to MC31 and for each of the meta storage circuits META STG0 to META STG31.

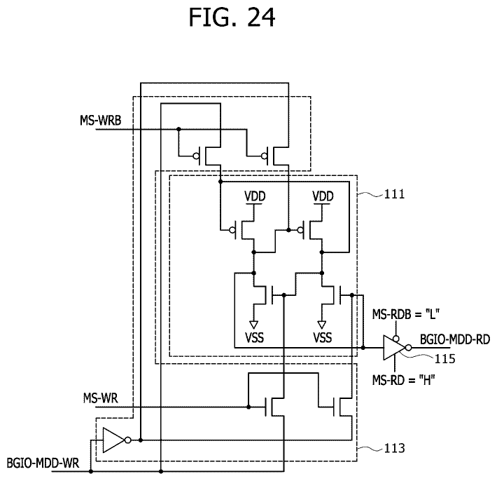

FIG. 24 illustrates a circuit of a meta register during an internal meta write operation including output to the read meta line BGIO-MDD-RD of metadata stored in the data latch 111. As illustrated in FIG. 24, for example, when an internal meta write operation is performed, while the latch output signal MS-RD is generated at a logic high level “H” and the inverted latch output signal MS-RDB is generated at a logic low level “L”, metadata stored in the data latch 111 are output to the read meta line BGIO-MDD-RD.

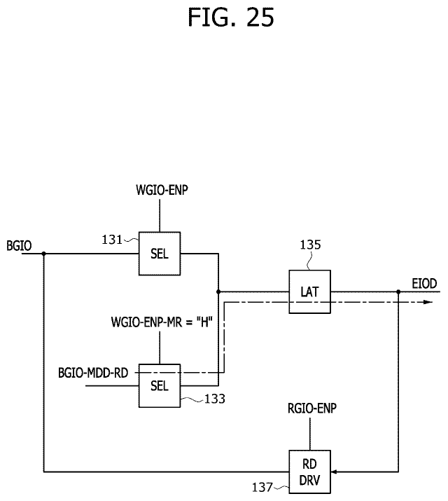

FIG. 25 illustrates an input and output line driver during an internal meta write operation including output to the internal line EIOD of metadata that are received through the read meta line BGIO-MDD-RD as shown by the dashed line. As illustrated in FIG. 25, for example, while the internal meta write pulse WGIO-ENP-MR is generated at a logic high level “H” when an internal meta write operation is performed, metadata that are received through the read meta line BGIO-MDD-RD are stored in the latch 135 through the selector 133. The metadata that are stored in the latch 135 are output to the internal line EIOD.

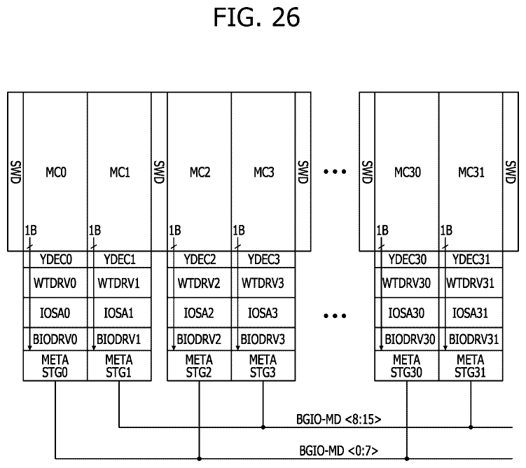

FIG. 26 illustrates a memory device during an internal meta read operation including storing in the meta storage circuit metadata that are output by the memory core. As illustrated in FIG. 26, 1 byte 1B or 8 bits of metadata (metadata totaling 32 bytes 32B or 256 bits) stored in each of the memory cores MC0 to MC31 may be output based on the column address BYAC and stored in each of the meta storage circuits META STG0 to META STG31.

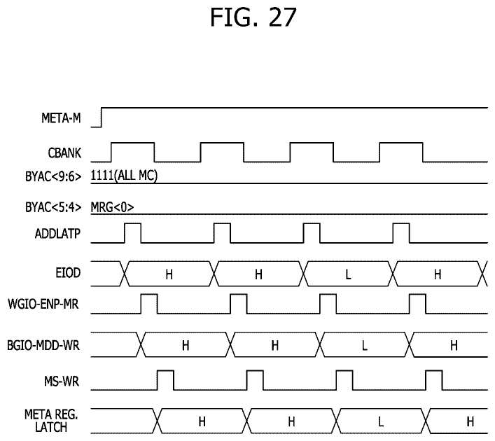

FIG. 27 illustrates a timing diagram during an internal meta read operation including outputting metadata by the memory cores and storing metadata in the meta storage circuits based on the column address BYAC<9:4>. As illustrated in FIG. 27, when the column bank signals CBANK are sequentially generated while an internal meta read operation is performed, the column address BYAC<9:4> is latched based on the address latch pulse ADDLATP. Because the memory cores MC0 to MC31 and the meta storage circuits META STG0 to META STG31 are selected based on the bit set “1111” of the column address BYAC<9:6>, and the first meta group signal MRG<0> and the column selection signal YI60 are selected based on the bit set “00” of the column address BYAC<5:4>, metadata at logic levels “H”, “H”, “L”, “H” and that are stored in memory cells that belong to the memory cores MC0 to MC31 and are accessed by the column selection signal YI60, are output to the internal line EIOD. Metadata at logic levels “H”, “H”, “L”, “H” and that are received through the internal line EIOD in synchronization with the internal meta write pulse WGIO-ENP-MR are output to the write meta line BGIO-MDD-WR. Metadata at logic levels “H”, “H”, “L”, “H” and that are input through the write meta line BGIO-MDD-WR in synchronization with the latch input signal MS-WR are stored in meta registers that belong to the meta storage circuits META STG0 to META STG31 and that are selected by the first meta group signal MRG<0>.

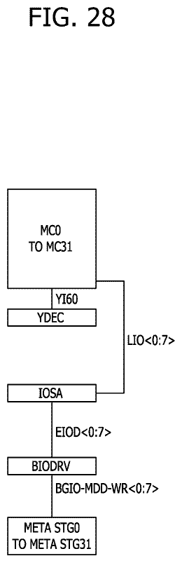

FIG. 28 illustrates a path along which metadata are output by the memory cores and metadata are stored in the meta storage circuits during an internal meta read operation in a memory device. As illustrated in FIG. 27 and FIG. 28, because the memory cores MC0 to MC31 and the meta storage circuits META STG0 to META STG31 are selected based on the bit set “1111” of the column address BYAC<9:6>, and the first meta group signal MRG<0> and the column selection signal YI60 are selected based on the bit set “00” of the column address BYAC<5:4>, metadata stored in memory cells that belong to each of the memory cores MC0 to MC31 and that are accessed by the column selection signal YI60 that is selected through the column decoder YDEC are output to the local lines LIO<0:7>. The metadata that are output to the local lines LIO<0:7> are sequentially output to the internal lines EIOD<0:7> and the write meta lines BGIO-MDD-WR<0:7> through the input and output sense amplifiers IOSA and the input and output line driver BIODRV. The metadata that are output to the write meta lines BGIO-MDD-WR<0:7> are stored in meta registers that belong to the meta storage circuits META STG0 to META STG31 and that are selected by the first meta group signal MRG<0> in synchronization with the latch input signal MS-WR. Although the memory cores MC0 to MC31, the column decoder YDEC, the input and output sense amplifiers IOSA, the input and output line driver BIODRV, and the meta storage circuits META STG0 to META STG31 are represented as one block in FIG. 28, the column decoder YDEC, the input and output sense amplifiers IOSA, the input and output line driver BIODRV may be separate components for each of the memory cores MC0 to MC31 and for each of the meta storage circuits META STG0 to META STG31.

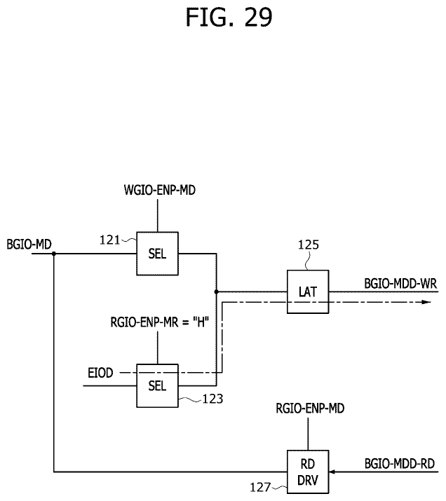

FIG. 29 illustrates a metadata driver during an internal meta read operation including output to the write meta line BGIO-MDD-WR of metadata that are received through the internal line EIOD as shown by the dashed line. As illustrated in FIG. 29, for example, while the internal meta write pulse WGIO-ENP-MR is generated at a logic high level “H” when an internal meta read operation is performed, metadata that are received through the internal line EIOD are stored in the latch 125 through the selector 123. The metadata that are stored in the latch 125 are output to the write meta line BGIO-MDD-WR.

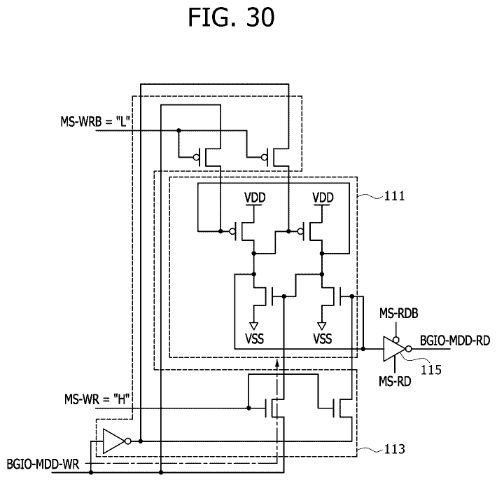

FIG. 30 illustrates a circuit of a meta register during an internal meta read operation including storing in the data latch 111 metadata that are received through the write meta line BGIO-MDD-WR as shown by the dashed line. As illustrated in FIG. 30, for example, when an internal meta read operation is performed, while the latch input signal MS-WR is generated at a logic high level “H” and the inverted latch input signal MS-WRB is generated at a logic low level “L”, metadata that are received through the write meta line BGIO-MDD-WR are stored in the data latch 111.

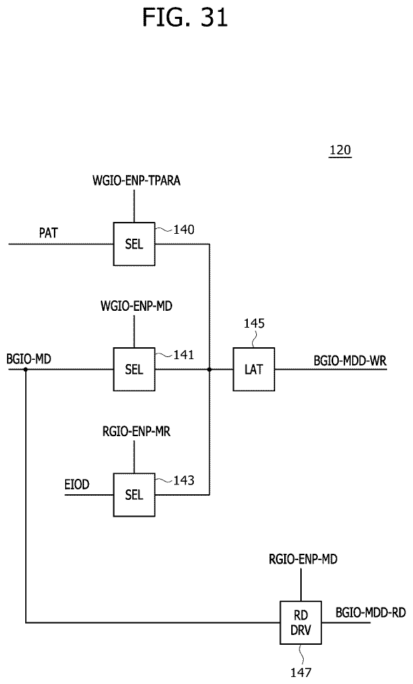

FIG. 31 illustrates an example of the metadata driver for a meta parallel-write operation. As illustrated in FIG. 31, in an embodiment, the metadata driver 120 includes selectors SEL 140, 141, and 143, a latch LAT 145, and a read driver RD DRV 147.

The selector 140 outputs a test voltage PAT based on a meta parallel-test pulse WGIO-ENP-TPARA that is generated when a meta parallel-write operation is performed. The selector 123 outputs the test voltage PAT that is a power source voltage VDD or a ground voltage VSS when a meta parallel-write operation is performed. The selector 141 outputs metadata that are received through the meta line BGIO-MD, based on the meta write pulse WGIO-ENP-MD that is generated when a meta parallel-write operation is performed. The selector 143 outputs metadata that are output by the memory core based on the internal meta read pulse RGIO-ENP-MR and that are received through the internal line EIOD, when an internal meta read operation is performed. For example, when a meta parallel-write operation is performed, the selectors 141 and 143 might not operate, but only the selector 140 may operate and output the test voltage PAT to the latch 145.

The latch 145 is electrically connected to the selectors 140, 141, and 143, latches metadata that are output by the selectors 140, 141, and 143, and outputs the latched metadata to the write meta line BGIO-MDD-WR. For example, when a meta parallel-write operation is performed, the latch 145 latches the test voltage PAT that is output by the selector 140 and outputs the latched test voltage PAT to the write meta line BGIO-MDD-WR. For example, when a meta write operation is performed, the latch 145 latches metadata that are output by the selector 141 and outputs the latched metadata to the write meta line BGIO-MDD-WR. For example, when an internal meta read operation is performed, the latch 145 latches metadata that are output by the selector 143 and outputs the latched metadata to the write meta line BGIO-MDD-WR. For example, when a meta parallel-write operation is performed, the test voltage PAT that is output to the write meta line BGIO-MDD-WR is stored in the meta storage circuit META STG in synchronization with the latch input signal MS-WR. The latch input signal MS-WR may be generated when a meta parallel-test operation is performed. An operation including storing the test voltage PAT of the write meta line BGIO-MDD-WR in the meta storage circuit META STG in synchronization with the latch input signal MS-WR is described in detail with reference to FIG. 5.

The read driver 147 outputs, to the meta line BGIO-MD, metadata that are output by the meta registers and received through the read meta line BGIO-MDD-RD, based on the meta read pulse RGIO-ENP-MD when a meta read operation is performed.

The metadata driver outputs the test voltage PAT to the write meta line BGIO-MDD-WR when a meta parallel-write operation is performed. The test voltage PAT that is output to the write meta line BGIO-MDD-WR is stored in the meta storage circuit META STG in synchronization with the latch input signal MS-WR.

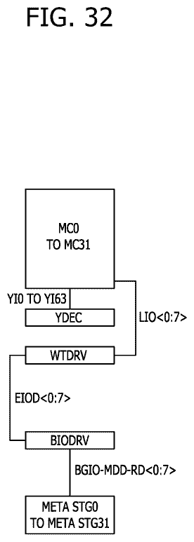

FIG. 32 illustrates a path along which the test voltage PAT is output by the meta storage circuits and a path along which the test voltage PAT is stored in the memory cores during a meta parallel-write operation in a memory device. As illustrated in FIG. 32, because all of the column selection signals YI0 to YI31 for each of the memory cores MC0 to MC31 are selected in the column decoder YDEC when a meta parallel-write operation is performed, the test voltages PAT stored in memory cells that belong to each of the meta storage circuits META STG0 to META STG31 and that are accessed by the column selection signals YI0 to YI31 are output to the read meta lines BGIO-MDD-RD<0:7> through the input and output line driver BIODRV. The test voltages PAT that are output are sequentially output to the internal lines EIOD<0:7> and the local lines LIO<0:7> through the input and output line driver BIODRV and the write driver WTDRV. The test voltages PAT that are output through the local lines LIO<0:7> are stored in all of memory cells that belong to each of the memory cores MC0 to MC31 and that are accessed by the column selection signals YI0 to YI63 that are selected by the column decoder YDEC. For example, when a meta parallel-write operation is performed, the test voltages PAT that are output by each of the meta storage circuits META STG0 to META STG31 are stored in all of the memory cells that are included in each of the memory cores MC0 to MC31. Although the memory cores MC0 to MC31, the column decoder YDEC, the write driver WTDRV, the input and output line driver BIODRV, and the meta storage circuits META STG0 to META STG31 are represented as one block in FIG. 32, the column decoder YDEC, the write driver WTDRV, the input and output line driver BIODRV may be separate components for each of the memory cores MC0 to MC31 and for each of the meta storage circuits META STG0 to META STG31.

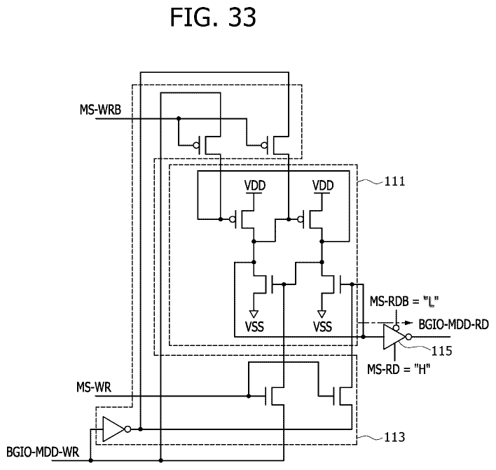

FIG. 33 illustrates a circuit of a meta register during a meta parallel-write operation including output to the read meta line BGIO-MDD-RD of the test voltage PAT that is stored in the data latch 111 as shown by the dashed line. As illustrated in FIG. 33, for example, when a meta parallel-write operation is performed, the latch output signal MS-RD is generated at a logic high level “H” and the inverted latch output signal MS-RDB is generated at a logic low level “L”, and the test voltage PAT stored in the data latch 111 is output to the read meta line BGIO-MDD-RD.

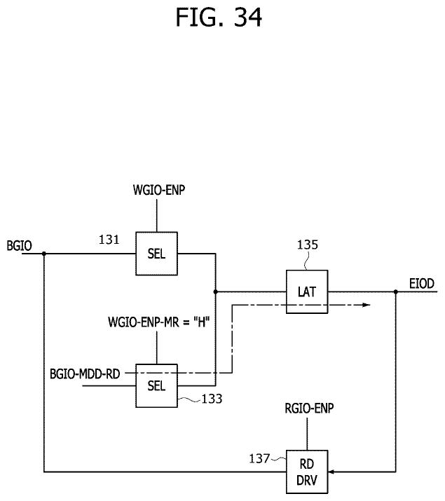

FIG. 34 illustrates an input and output line driver during a meta parallel-write operation including output to the internal line EIOD of metadata that are received through the read meta line BGIO-MDD-RD as shown by the dashed line. As illustrated in FIG. 34, while the internal meta write pulse WGIO-ENP-MR is generated at a logic high level “H” when a meta parallel-write operation is performed, for example, metadata that are received through the read meta line BGIO-MDD-RD are stored in the latch 135 through the selector 133. The metadata that are stored in the latch 135 are output to the internal line EIOD.

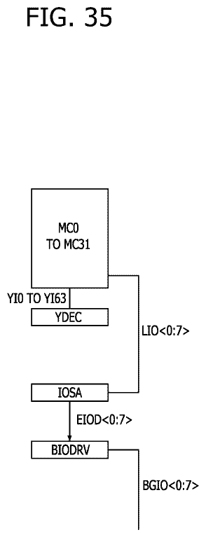

FIG. 35 illustrates a path along which the test voltages PAT stored in the memory cores are output during a meta parallel-read operation in a memory device. As illustrated in FIG. 35, for example, when a meta parallel-read operation is performed, the test voltages PAT stored in all of memory cells that belong to each of the memory cores MC0 to MC31 and that are accessed by the column selection signals YI0 to YI63 that are selected in the column decoder YDEC are output to the local lines LIO<0:7>. The test voltages PAT that are output to the local lines LIO<0:7> are sequentially output to the internal lines EIOD<0:7> and the external lines BGIO<0:7> through the input and output sense amplifiers IOSA and the input and output line driver BIODRV. Although the memory cores MC0 to MC31, the column decoder YDEC, the input and output sense amplifiers IOSA, and the input and output line driver BIODRV are represented as one block in FIG. 35, the column decoder YDEC, the input and output sense amplifiers IOSA, and the input and output line driver BIODRV may be separate components for each of the memory cores MC0 to MC31.

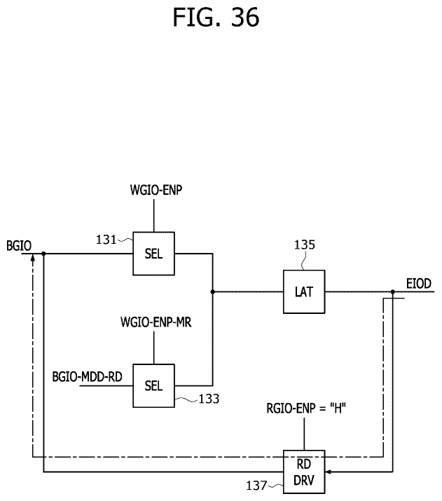

FIG. 36 illustrates an input and output line driver during a meta parallel-read operation including output to the external line BGIO of data that are received through the internal line EIOD as shown by the dashed line. As illustrated in FIG. 36, when a meta parallel-read operation is performed, while the read pulse RGIO-ENP is generated at a logic high level “H”, data that are received through the internal line EIOD are output to the external line BGIO through the read driver 137.

The embodiments of the present disclosure are described. A person having ordinary knowledge in the art will understand that various modifications, additions, and substitutions are possible without departing from the scope and technical concepts of the present disclosure. Accordingly, the disclosed embodiments should be considered from a descriptive viewpoint and not from a restrictive viewpoint. Therefore, the scope of the present disclosure is not limited to the above descriptions. All changes within the meaning and range of equivalency of the claims are included within their scope.

What is claimed is:

1. A memory device comprising:
a plurality of memory cores; and
a plurality of meta storage circuits, each of the plurality of meta storage circuits corresponding to a different one of the plurality of memory cores;
wherein, when a meta write operation is performed, data that are received through an external line are stored in the plurality of memory cores based on a column address, and metadata that are received through a meta line are stored in a meta storage circuit, among the plurality of meta storage circuits, that is selected by the column address.

2. The memory device of claim 1, wherein when the meta write operation is performed, a column selection signal is selected by the column address, and the data are stored in memory cells that belong to the plurality of memory cores and that are accessed by the selected column selection signal.

3. The memory device of claim 2, further comprising:
an input and output line driver configured to output the data to an internal line when the meta write operation is performed;
a write driver configured to output, to a local line, the data that are received through the internal line when the meta write operation is performed; and
a column decoder configured to generate the column selection signal based on the column address when the meta write operation is performed.

4. The memory device of claim 1,
wherein each of the meta storage circuits comprises a plurality of metadata drivers and a plurality of meta registers;
wherein each of the plurality of metadata drivers corresponds to at least one meta register among the plurality of meta registers; and
wherein at least one of the plurality of metadata drivers and at least one of the plurality of meta registers are selected by a meta group signal.

5. The memory device of claim 1, wherein each of the meta storage circuits comprises:
a metadata driver configured to output the metadata to the write meta line when the meta write operation is performed; and
a meta register configured to store the metadata that are received through the write meta line in a data latch that is selected by the column address when the meta write operation is performed.

6. The memory device of claim 1, wherein:
when a meta read operation is performed, the data stored in the plurality of memory cores are output to the external line based on the column address; and
when the meta read operation is performed, the metadata stored in the meta storage circuit that is selected by the column address are output to the meta line.

7. The memory device of claim 6, wherein, when the meta read operation is performed, a column selection signal is selected by the column address, and data stored in memory cells that belong to the plurality of memory cores and that are accessed by the selected column selection signal are output.

8. The memory device of claim 7, further comprising:
a column decoder configured to generate the column selection signal based on the column address when the meta read operation is performed;
an input and output sense amplifier configured to receive, through a local line, the data that are output by the plurality of memory cores and output the data to an internal line, based on the column selection signal when the meta read operation is performed; and
an input and output line driver configured to output, to the external line, the data that are received through the internal line when the meta read operation is performed.

9. The memory device of claim 6, wherein each of the meta storage circuits further comprises:
a meta register configured to output, to a read meta line, the metadata stored in a data latch that is selected by the column address when the meta read operation is performed; and
a metadata driver configured to output, to the meta line, the metadata that are received through the read meta line when the meta read operation is performed.

10. The memory device of claim 1, wherein:
when an internal meta write operation is performed, the metadata stored in the plurality of meta storage circuits are output to a read meta line based on the column address, and
when the internal meta write operation is performed, the metadata that are received through the read meta line are stored in the plurality of memory cores based on the column address.

11. The memory device of claim 10, wherein each of the meta storage circuits comprises a meta register configured to output, to the read meta line, the metadata stored in a data latch that is selected by the column address when the internal meta write operation is performed.

12. The memory device of claim 11, wherein when the internal meta write operation is performed, a column selection signal is selected by the column address, and the metadata are stored in memory cells that belong to the plurality of memory cores and that are accessed by the selected column selection signal.

13. The memory device of claim 12, further comprising:
an input and output line driver configured to output, to an internal line, the metadata that are received through the read meta line when the internal meta write operation is performed;
a write driver configured to output, to a local line, the metadata that are received through the internal line when the internal meta write operation is performed; and
a column decoder configured to generate the column selection signal based on the column address when the meta write operation is performed.

14. The memory device of claim 1, wherein:
when an internal meta read operation is performed, the metadata stored in the plurality of memory cores are output to a write meta line based on the column address, and
when the internal meta read operation is performed, the metadata that are received through the write meta line are stored in the plurality of meta storage circuits based on the column address.

15. The memory device of claim 14, wherein when the internal meta read operation is performed, a column selection signal is selected by the column address, and the metadata stored in memory cells that belong to the plurality of memory cores and that are accessed by the selected column selection signal are output.

16. The memory device of claim 15, further comprising:
a column decoder configured to generate the column selection signal based on the column address when the internal meta read operation is performed;
an input and output sense amplifier configured to receive the metadata that are output by the plurality of memory cores through a local line and output the metadata to an internal line, based on the column selection signal when the internal meta read operation is performed; and
an input and output line driver configured to output, to the write meta line, the data that are received through the internal line when the internal meta read operation is performed.

17. The memory device of claim 14, wherein each of the meta storage circuits stores the metadata that are received through the write meta line in a data latch that is selected by the column address, when the internal meta read operation is performed.

18. A memory device comprising:
a plurality of memory cores; and
a plurality of meta storage circuits, each of the plurality of meta storage circuits corresponding to a different one of the plurality of memory cores;
wherein, when a meta read operation is performed, data stored in the plurality of memory cores are output to an external line based on a column address, and
wherein, when the meta read operation is performed, metadata stored in a meta storage circuit, among the plurality of meta storage circuits, that is selected by the column address are output to a meta line.

19. The memory device of claim 18, wherein, when the meta read operation is performed, a column selection signal is selected by the column address, and data stored in memory cells that belong to the plurality of memory cores and that are accessed by the selected column selection signal are output.

20. The memory device of claim 19, further comprising:
a column decoder configured to generate the column selection signal based on the column address when the meta read operation is performed;
an input and output sense amplifier configured to receive, through a local line, the data that are output by the plurality of memory cores and output the data to an internal line, based on the column selection signal when the meta read operation is performed; and
an input and output line driver configured to output, to the external line, the data that are received through the internal line when the meta read operation is performed.

21. The memory device of claim 18, wherein each of the meta storage circuits further comprises:
a meta register configured to output, to a read meta line, the metadata stored in a data latch that is selected by the column address when the meta read operation is performed; and
a metadata driver configured to output, to the meta line, the metadata that are received through the read meta line when the meta read operation is performed.

22. A memory device comprising:
a plurality of memory cores; and
a plurality of meta storage circuits, each of the plurality of meta storage circuits corresponding to a different one of the plurality of memory cores;
wherein, when an internal meta write operation is performed, metadata stored in the plurality of meta storage circuits are output to a read meta line based on a column address; and
wherein, when the internal meta write operation is performed, the metadata that are received through the read meta line are stored in the plurality of memory cores based on the column address.

23. The memory device of claim 22, wherein each of the meta storage circuits comprises a meta register configured to output, to a read meta line, the metadata stored in a data latch that is selected by the column address when the internal meta write operation is performed.

24. The memory device of claim 23, wherein when the internal meta write operation is performed, a column selection signal is selected by the column address, and the metadata are stored in memory cells that belong to the plurality of memory cores and that are accessed by the selected column selection signal.

25. A memory device comprising:
a plurality of memory cores; and
a plurality of meta storage circuits, each of the plurality of meta storage circuits corresponding to a different one of the plurality of memory cores;
wherein, when an internal meta read operation is performed, metadata stored in the plurality of memory cores are output to a write meta line based on a column address; and
wherein, when the internal meta read operation is performed, the metadata that are received through the write meta line are stored in the plurality of meta storage circuits based on the column address.

26. The memory device of claim 25, wherein when the internal meta read operation is performed, a column selection signal is selected by the column address, and the metadata stored in memory cells that belong to the plurality of memory cores and that are accessed by the selected column selection signal are output.

27. The memory device of claim 26, further comprising:
a column decoder configured to generate the column selection signal based on the column address when the internal meta read operation is performed;
an input and output sense amplifier configured to receive, through a local line, the metadata that are output by the plurality of memory cores and output the metadata to an internal line, based on the column selection signal when the internal meta read operation is performed; and
an input and output line driver configured to output, to the write meta line, the metadata that are received through the internal line when the internal meta read operation is performed.

28. The memory device of claim 25, wherein each of the meta storage circuits stores the metadata that are received through the write meta line in a data latch that is selected by the column address when the internal meta read operation is performed.

29. A memory device comprising:
a plurality of memory cores; and
a plurality of meta storage circuits, each of the plurality of meta storage circuits corresponding to a different one of the plurality of memory cores;
wherein when a meta parallel-write operation is performed, a test voltage is stored in the plurality of meta storage circuits,
when the meta parallel-write operation is performed, the test voltage stored in the plurality of meta storage circuits is stored in the plurality of memory cores, and
when a meta parallel-read operation is performed, the test voltage that is stored in the plurality of memory cores is output to an external line.

30. The memory device of claim 29, wherein the test voltage is a power source voltage or a ground voltage.

31. The memory device of claim 29, wherein each of the plurality of meta storage circuits comprises:
a metadata driver configured to output the test voltage to a write meta line when the meta parallel-write operation is performed; and
a meta register configured to store the test voltage that is received through the write meta line in a data latch when the meta parallel-write operation is performed.

32. The memory device of claim 29, wherein:
when the meta parallel-write operation is performed, the test voltage stored in the plurality of meta storage circuits is output to a read meta line, and
when the meta parallel-write operation is performed, the test voltage that is received through the read meta line is stored in the plurality of memory cores.

33. The memory device of claim 32, wherein when the meta parallel-write operation is performed, all of column selection signals are selected, and the test voltage is stored in memory cells that belong to the plurality of memory cores and that are accessed by all of the column selection signals.

34. The memory device of claim 29, wherein when the meta parallel-read operation is performed, all of column selection signals are selected, and the test voltage stored in memory cells that belong to the plurality of memory cores and that are accessed by all of the column selection signals is output.

35. The memory device of claim 34, further comprising:
a column decoder configured to select all of the column selection signals when the meta parallel-read operation is performed;
an input and output sense amplifier configured to receive the test voltage that is output by the plurality of memory cores through a local line and output the test voltage to an internal line, based on the column selection signal when the meta parallel-read operation is performed; and
an input and output line driver configured to output, to the external line, the test voltage that is received through the internal line, when the meta parallel-read operation is performed.

36. A method of processing metadata, the method comprising:
when the meta write operation is performed, storing data that are received through an external line in a plurality of memory cores, based on a column address; and
when the meta write operation is performed, storing metadata that are received through a meta line in a meta storage circuit, among a plurality of meta storage circuits, that is selected by the column address.

37. A method of processing metadata, the method comprising:
when a meta read operation is performed, outputting to an external line data stored in a plurality of memory cores based on a column address; and
when the meta read operation is performed, outputting to a meta line metadata stored in a meta storage circuit, among a plurality of meta storage circuits, that is selected by the column address.

38. A method of processing metadata, the method comprising:
when an internal meta write operation is performed, outputting to a read meta line metadata stored in a plurality of meta storage circuits based on a column address; and
when the internal meta write operation is performed, storing the metadata that are received through the read meta line in a plurality of memory cores based on the column address.

39. A method of processing metadata, the method comprising:
when an internal meta read operation is performed, outputting to a write meta line metadata stored in a plurality of memory cores based on a column address; and
when the internal meta read operation is performed, storing metadata that are received through the write meta line in a plurality of meta storage circuits based on the column address.

40. A method of processing metadata, the method comprising:
storing a test voltage in a plurality of meta storage circuits when a meta parallel-write operation is performed;
storing the test voltage stored in the plurality of meta storage circuits in a plurality of memory cores when the meta parallel-write operation is performed; and
outputting, to an external line, the test voltage that is stored in the plurality of memory cores when the meta parallel-read operation is performed.
